(19) United States
(12) Patent Application Publication
(10) Pub. No.: US 2024/0332249 A1
(43) Pub. Date: Oct. 3, 2024

(54) BONDING APPARATUS AND BONDING METHOD USING THE SAME

(71) Applicant: Samsung Display Co., LTD., Yongin-si (KR)

(72) Inventors: JEONGMIN BAE, Yongin-si (KR); SUNGLAE KIM, Yongin-si (KR); JUNSEOK AHN, Yongin-si (KR); YEONGHO HA, Yongin-si (KR)

(21) Appl. No.: 18/536,865

(22) Filed: Dec. 12, 2023

(30) Foreign Application Priority Data
Mar. 29, 2023 (KR) 10-2023-0041007

(51) Int. Cl. H01L 23/00

(52) U.S. Cl. CPC H01L 24/83; H01L 24/75; H01L 2224/75701; H01L 2224/75753; H01L 2224/75804; H01L 2224/8313

(57) ABSTRACT

Provided is a bonding apparatus. The bonding apparatus includes a first stage on which a display panel including a first mark is disposed, a pressing part disposed above the first stage and configured to provide a data driver including a second mark on the display panel, and an alignment camera disposed below the first stage. When the data driver is provided on the display panel such that the data driver and the display panel are connected to each other, the alignment camera is configured to capture images of the first mark and the second mark at a same temporal instance.

This application claims priority to Korean Patent Application No. 10-2023-0041007, filed on Mar. 29, 2023, and all the benefits accruing therefrom under 35 U.S.C. § 119, the content of which in its entirety is herein incorporated by reference.

### BACKGROUND

### Field

The present disclosure herein relates to a bonding apparatus and a bonding method using the same.

### Description of the Related Art

Electronic equipment for providing an image to a user such as, for example, smartphones, digital cameras, laptop computers, navigations, and smart televisions, may include a display device for displaying an image. The display device may generate an image to provide the image to the user through a display screen.

A display device may include a display panel that displays an image. The display panel may include a plurality of gate lines, a plurality of data lines, and a plurality of pixels connected to the plurality of gate lines and the plurality of data lines.

The display panel may be connected to data driver that provides an electrical signal to the gate lines or data lines for displaying an image.

### SUMMARY

The present disclosure provides a bonding apparatus capable aligning and bonding a data driver to one side of a display panel with increased accuracy compared to some other techniques. The present disclosure provides a bonding method capable of being implemented by the bonding apparatus.

An embodiment of the present disclosure provides a bonding apparatus including: a first stage on which a display panel including a first mark is disposed; a pressing part disposed above the first stage and configured to provide a data driver including a second mark on the display panel; and an alignment camera disposed below the first stage, where, when the data driver is provided on the display panel such that the data driver and the display panel are connected to each other, the alignment camera is configured to capture images of the first mark and the second mark at a same temporal instance.

In an embodiment of the present disclosure, a bonding method includes: providing a display panel including a first mark on a first stage, where a plane of the first stage is defined by a first direction and a second direction crossing the first direction; connecting a data driver including a second mark to the display panel; capturing a first image of the first mark and a second image of the second mark by an alignment camera disposed below the first stage, wherein the first image of the first mark and the second image of the second mark are captured at a same temporal instance; and aligning the display panel and the data driver.

### BRIEF DESCRIPTION OF THE DRAWINGS

The accompanying drawings are included to provide a further understanding of the example aspects of present disclosure and are incorporated in and constitute a part of this specification. The drawings illustrate example embodiments of supported by the present disclosure and, together with the description, serve to explain principles of the present disclosure. In the drawings:

FIG. 1 is a perspective view of a bonding apparatus according to one or more embodiments of the present disclosure;

FIG. 2 is a perspective view of an embodiment of a cover of FIG. 1;

FIG. 3 is a perspective view of an embodiment of an alignment camera of FIG. 1;

FIG. 4 is a perspective view of an embodiment of an electronic apparatus including a display panel manufactured using the bonding apparatus of FIG. 1;

FIG. 5 is an exploded perspective view of an embodiment of the electronic apparatus of FIG. 4;

FIG. 6 is a cross-sectional view of a display device of FIG. 5;

FIGS. 7A and 7B are plan views of a display panel of FIG. 6;

FIG. 8 is a view illustrating an example of a bent state of a bending part of FIGS. 7A and 7B;

FIG. 9 is an enlarged perspective view of an embodiment of pad areas of FIGS. 7A and 7B;

FIG. 10 is a view obtained by imaging a data driver and a display panel of FIG. 9 using an embodiment of imaging parts of FIG. 1;

FIGS. 11A to 11I are views for explaining a bonding method using an embodiment of the bonding apparatus of FIG. 1;

FIG. 12 is a cross-sectional view of a bonding apparatus according to another embodiment of the present disclosure;

FIG. 13 is a perspective view of a bonding apparatus according to another embodiment of the present disclosure;

FIG. 14 is a perspective view of a bonding apparatus according to another embodiment of the present disclosure; and

FIGS. 15A and 15B are example views of embodiments of a display panel of FIGS. 13 and 14.

### DETAILED DESCRIPTION

Advantages and features of the present disclosure and implementation methods thereof will be clarified through the following example embodiments described with reference to the accompanying drawings.

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, example embodiments of the present disclosure will be described below in more detail with reference to the accompanying drawings.

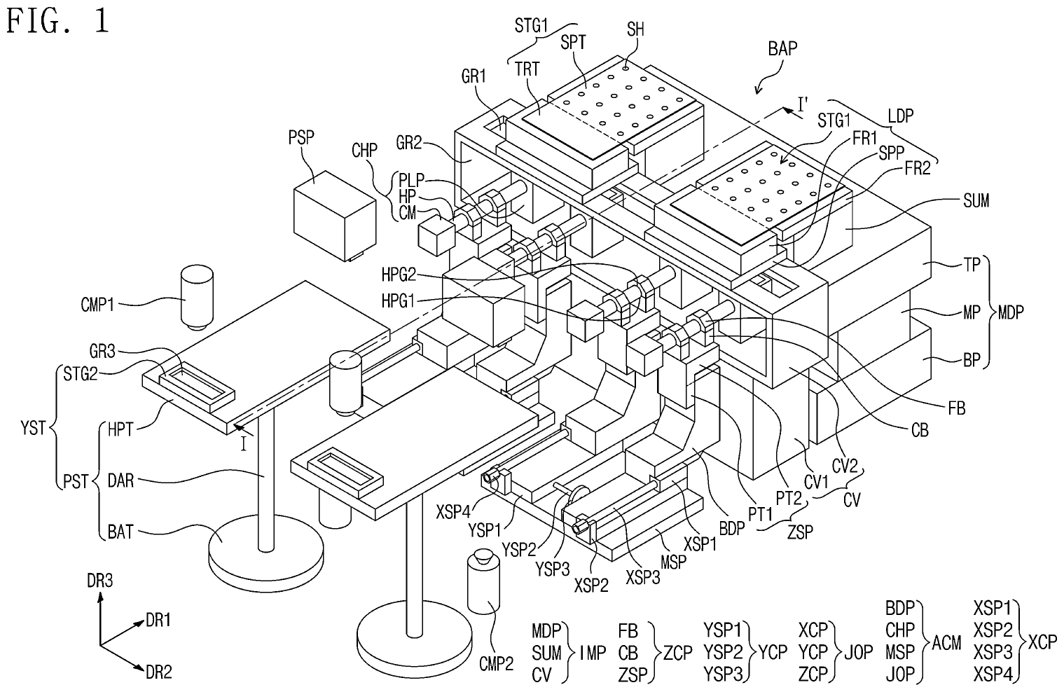

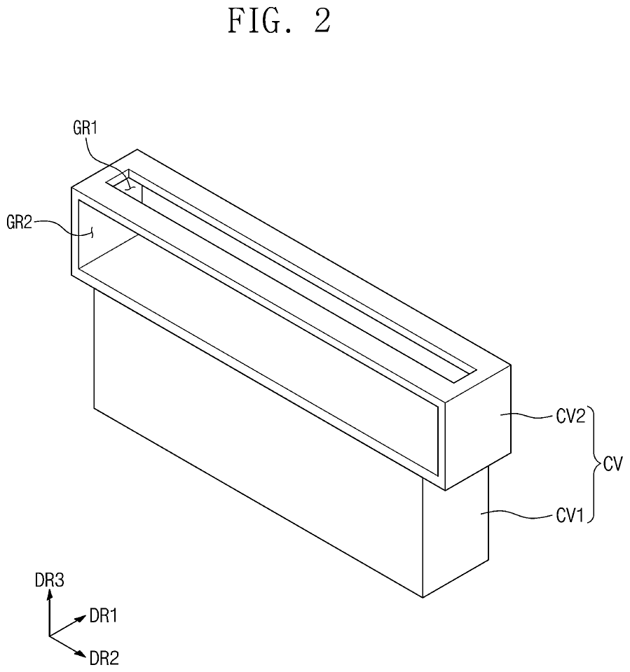

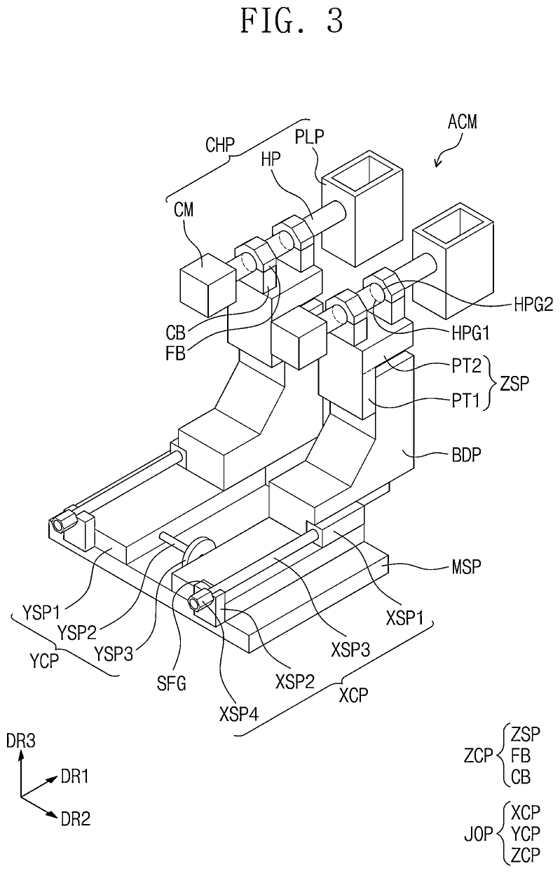

FIG. 1 is a perspective view of a bonding apparatus according to one or more embodiments of the present disclosure. FIG. 2 is a perspective view of an embodiment of a cover of FIG. 1. FIG. 3 is a perspective view of an embodiment of an alignment camera of FIG. 1.

Referring to FIG. 1, a bonding apparatus BAP may include an alignment camera ACM, a coupling part IMP, pressing parts PSP, panel fixing parts LDP, a preliminary stage YST, first camera parts CMP1, and second camera parts CMP2.

The coupling part IMP may include a controller MDP, a plurality of motors SUM, and a cover CV. The motor SUM may be disposed on the controller MDP. The cover CV and the controller MDP may be arranged in a first direction DR1. One side of opposite sides of the controller MDP in the first direction DR1 may be in contact with the cover CV. One side of opposite sides of each of the motors SUM in the first direction DR1 may be in contact with the cover CV. One side of each of the controller MDP and the motors SUM may be defined as a side facing the alignment camera ACM.

The controller MDP may include an upper controller TP, a middle controller MP, and a lower controller BP. The lower controller BP, the middle controller MP, and the upper controller TP may be sequentially stacked.

The upper controller TP may have a rectangular parallelepiped shape. When viewed in a plan view, a top surface of the upper controller TP may have a rectangular shape having shorter sides extending in the first direction DR1 and longer sides extending in a second direction DR2. However, the embodiments of the present disclosure are not limited thereto, and the upper controller TP may have other various shapes (e.g., a circular shape, a polygonal shape). It is to be understood that the terms “longer” and “shorter,” when recited with respect to a shape of an object (e.g., “longer sides” and “shorter sides” of an object), are relative terms expressing dimensions of the object.

In the example descriptions herein, a direction that substantially perpendicularly crosses a plane defined by the first direction DR1 and the second direction DR2 is defined as a third direction DR3. In this specification, the term “viewed from the plane” may mean a state viewed in the third direction DR3.

When viewed in the second direction DR2, the upper controller TP may have a rectangular shape having longer sides extending in the first direction DR1 and shorter sides extending in the third direction DR3.

The middle controller MP may be disposed below the upper controller TP. The middle controller MP may be connected to the upper controller TP. It is to be understood that the term “connected to” may include physical coupling or electrical coupling between elements described herein. When viewed in the second direction DR2, the middle controller MP may have a rectangular shape having longer sides extending in the first direction DR1 and shorter sides extending in the third direction DR3. A center of each of the longer sides of the middle controller MP and a center of each of the longer sides of the upper controller TP may match each other (e.g., along an axis parallel to the second direction DR2). In some examples, a length of each of the longer sides of the middle controller MP may be less than a length of each of the longer sides of the upper controller TP.

The lower controller BP may be disposed below the middle controller MP. When viewed in the second direction DR2, the lower controller BP may have a rectangular shape having longer sides extending in the first direction DR1 and shorter sides extending in the third direction DR3. A center of each of the longer sides of the lower controller BP may match a center of each of the longer sides of the middle controller MP (e.g., along the second direction DR2). The center of each of the longer sides of the lower controller BP may match the center of each of the longer sides of the upper controller TP (e.g., along the second direction DR2). For example, a length of each of the longer sides of the lower controller BP may be greater than the length of each of the longer sides of the middle controller MP.

Both surfaces of the upper controller TP that are opposite to each other in the second direction DR2 may be disposed on the same plane as both surfaces of the middle controller MP that are opposite to each other in the second direction DR2. Both surfaces of the lower controller BP that are opposite to each other in the second direction DR2 may be disposed on the same plane as both surfaces of the middle controller MP that are opposite to each other in the second direction DR2.

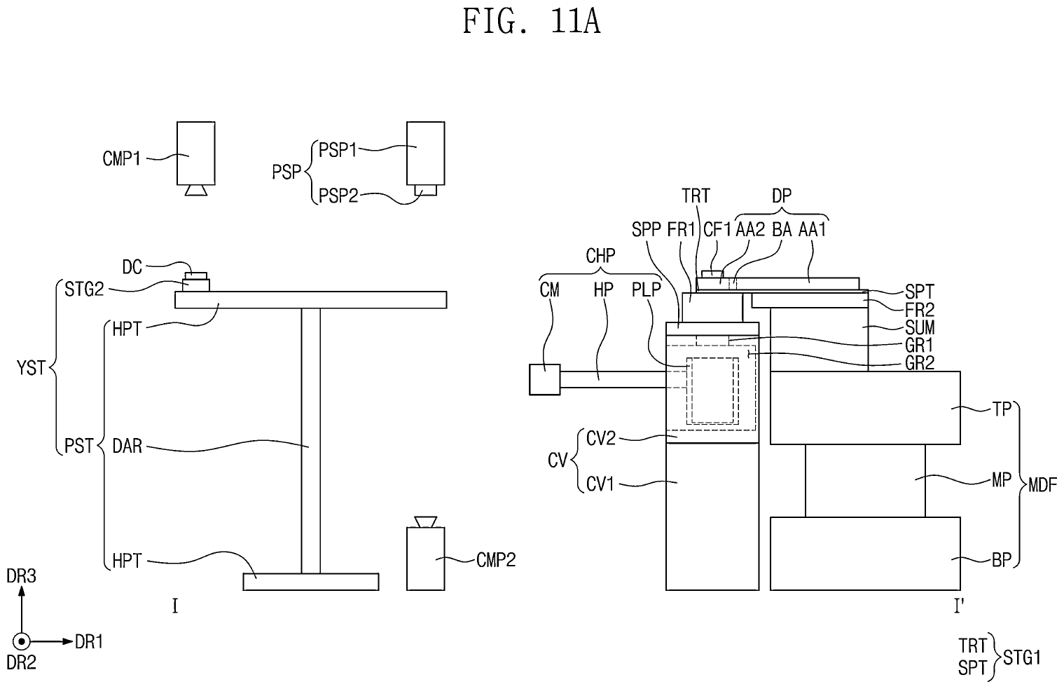

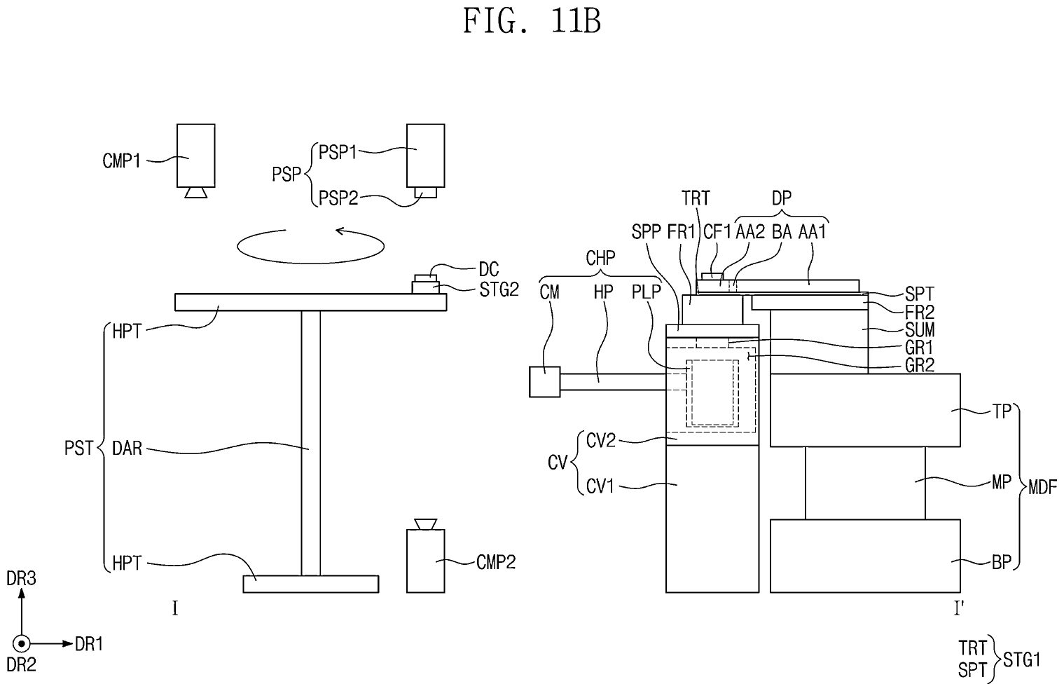

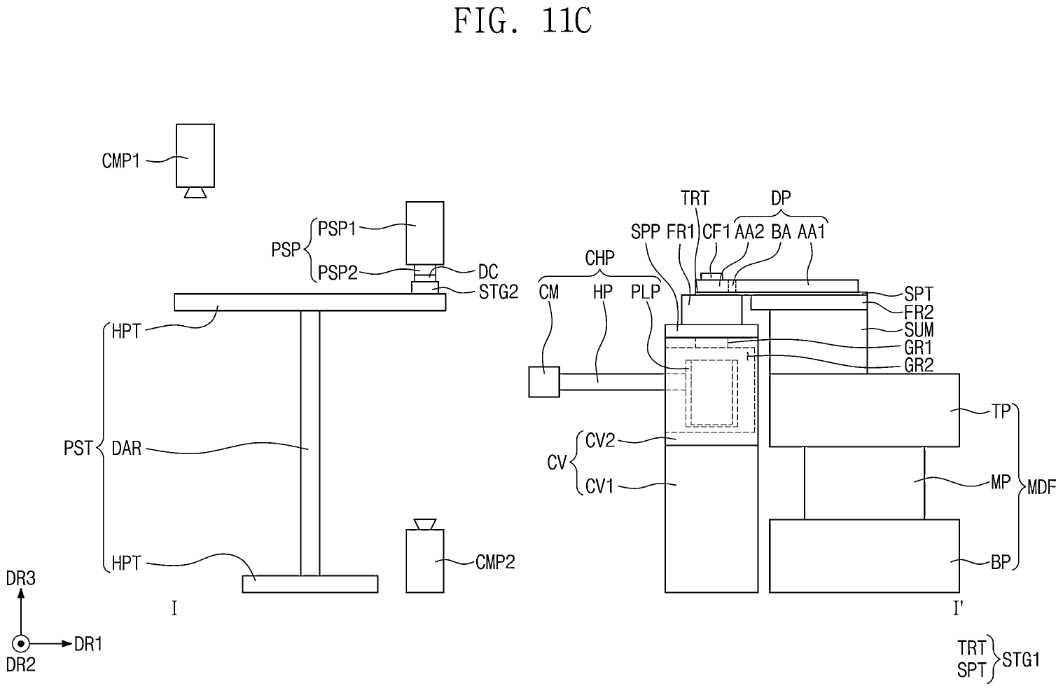

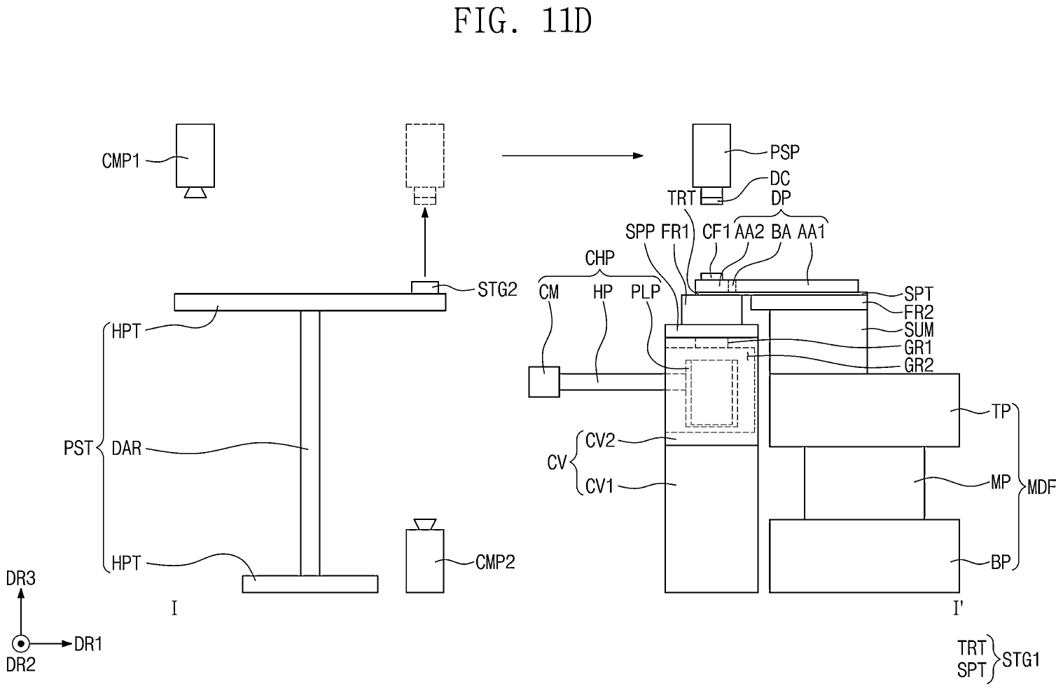

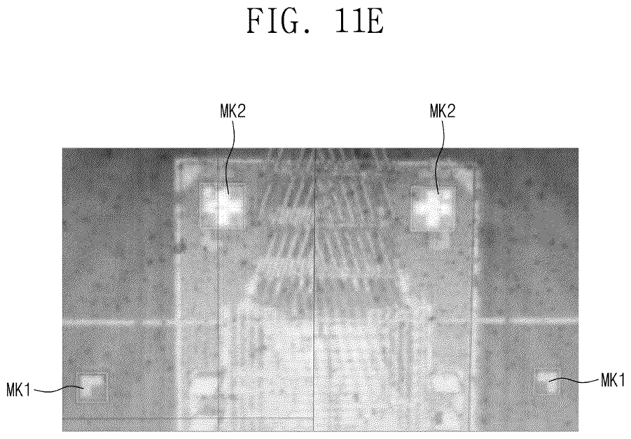

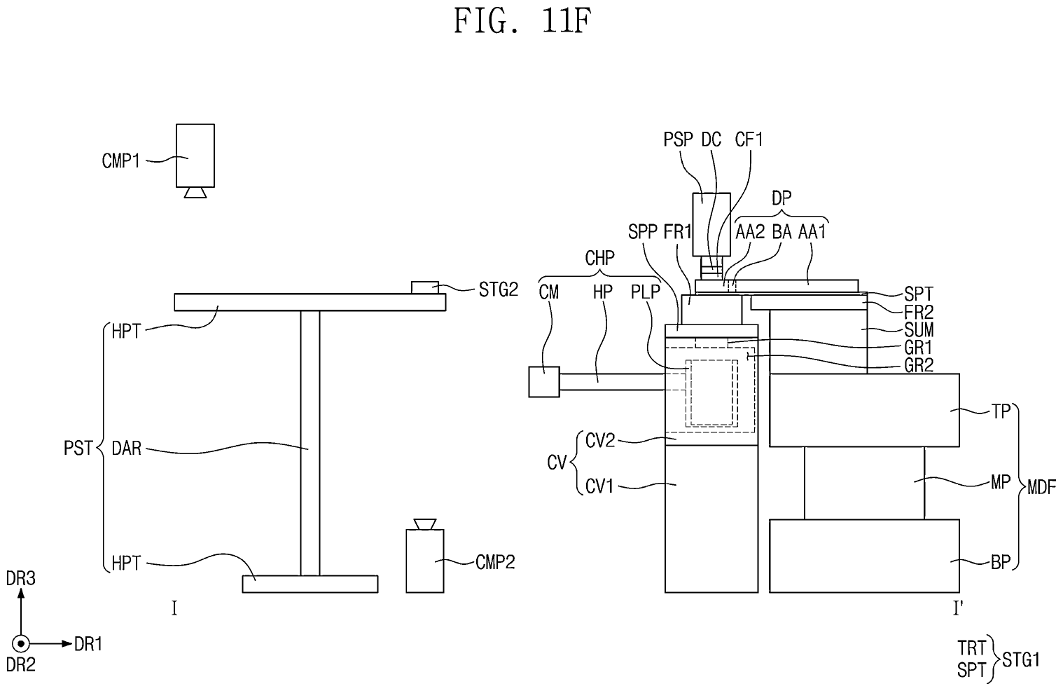

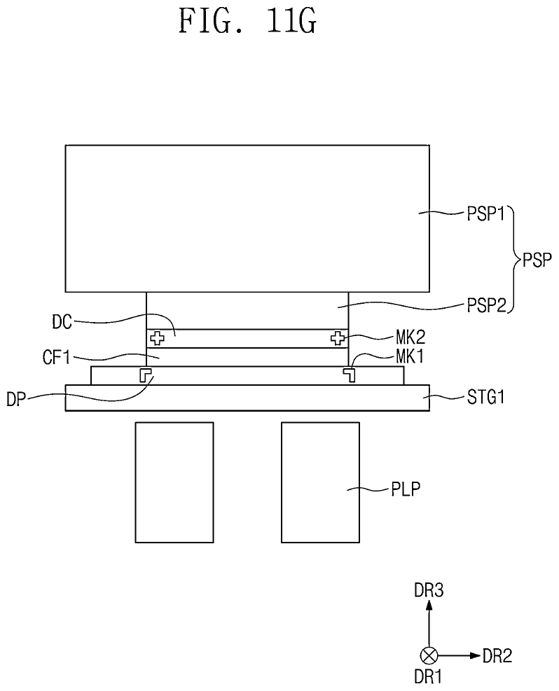

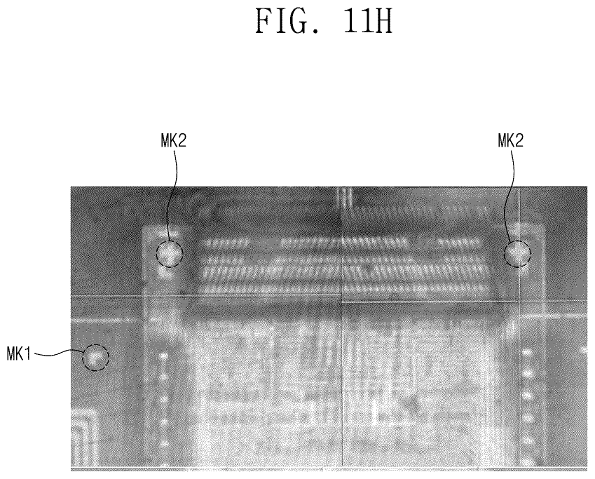

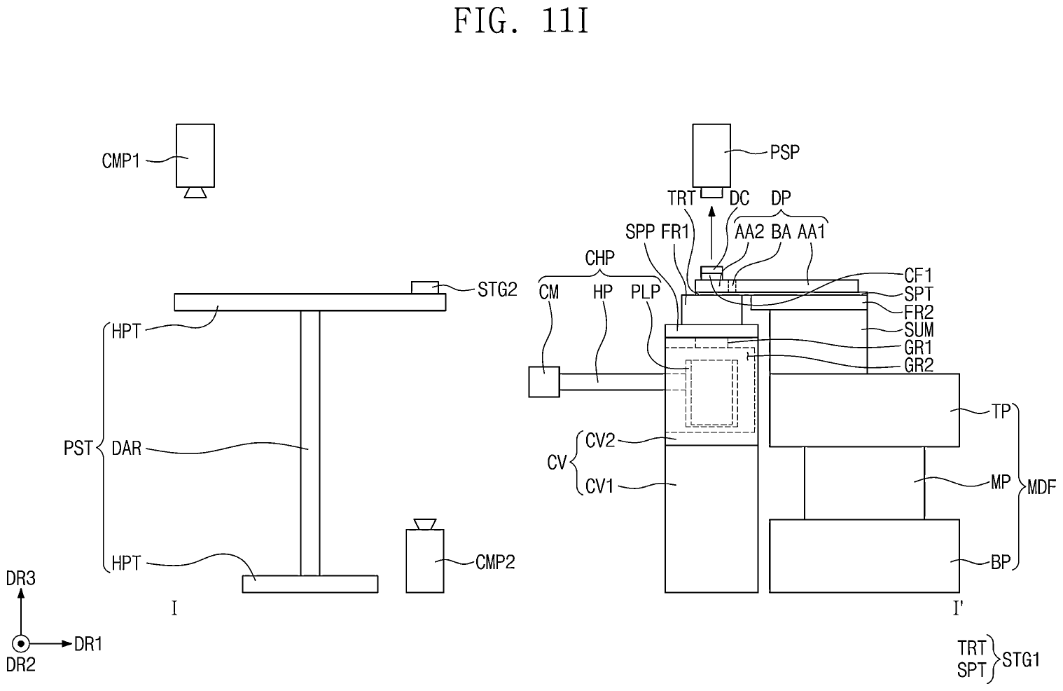

Although not shown, the middle controller MP is movable in at least one of the first direction DR1, the second direction DR2, or the third direction DR3 along a top surface of the lower controller BP. When the middle controller MP moves, the upper controller TP connected to the middle controller MP may move in the same direction as the movement direction of the middle controller MP. The movement of the middle controller MP and the upper controller TP will be described in detail with reference to FIGS. 11D, 11F, and 11G.

Referring to FIGS. 1 and 2, the cover CV may include a first cover CV1 and a second cover CV2. The first cover CV1 may have a rectangular parallelepiped shape. When viewed in the first direction DR1, the first cover CV1 may have a rectangular shape having longer sides extending in the second direction DR2 and shorter sides extending in the third direction DR3.

The second cover CV2 may be disposed on the first cover CV1. The second cover CV2 may have a rectangular parallelepiped shape. When viewed in the first direction DR1, the second cover CV2 may have a rectangular shape having longer sides extending in the second direction DR2 and shorter sides extending in the third direction DR3.

When viewed in the first direction DR1, a center of the longer side of the first cover CV1 may match a center of the longer side of the second cover CV2. When viewed in the first direction DR1, a length of the second cover CV2 in the second direction DR2 may be greater than the length of the first cover CV1 in the second direction DR2. When viewed from the first direction DR1, a length of the second cover CV2 in the third direction DR3 may be less than the length of the first cover CV1 in the third direction DR3.

A first groove GR1 may be defined in a top surface of the second cover CV2. The first groove GR1 may extend in the second direction DR2. When viewed in the plan view, the first groove GR1 may have a rectangular shape.

A second groove GR2 may be defined in one of opposite sides of the second cover CV2 in the first direction DR1. One surface of the second cover CV2 may be defined as a surface facing the alignment camera ACM. When viewed in the first direction DR1, the second groove GR2 may have a rectangular shape having longer sides extending in the second direction DR2 and shorter sides extending in the third direction DR3. Substantially, the first groove GR1 and the second groove GR2 may be defined to be integrated with each other.

Referring to FIG. 1, the plurality of motors SUM may be disposed on the controller MDP. The motors SUM may be disposed on the top surface of the upper controller TP. The motors SUM and the upper controller TP may be connected to each other.

According to one or more embodiments of the present disclosure, although two motors SUM are illustrated, the number of motors SUM is not limited thereto, and one motor SUM or more than two motors SUM may be disposed on the controller MDP.

When viewed in the second direction DR2, each of side surfaces of a motor SUM, which are opposite to each other in the second direction DR2, may have a rectangular shape.

The motors SUM may convert adsorption holes SH defined in an adsorption part SPT into a vacuum state. Aspects of the adsorption part SPT are later described herein. The conversion of the adsorption holes SH into the vacuum state will be described in detail with reference to FIG. 11A.

Each of the plurality of panel fixing parts LDP may be disposed on a corresponding motor SUM of the motors SUM. Each of the panel fixing parts LDP may be disposed on the cover CV.

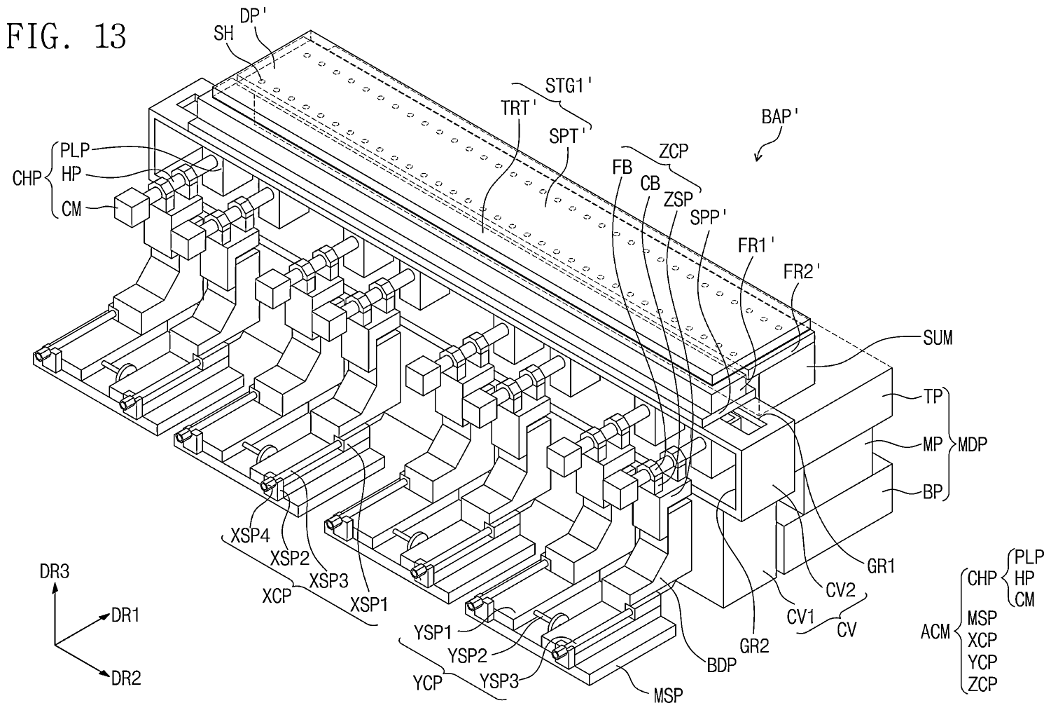

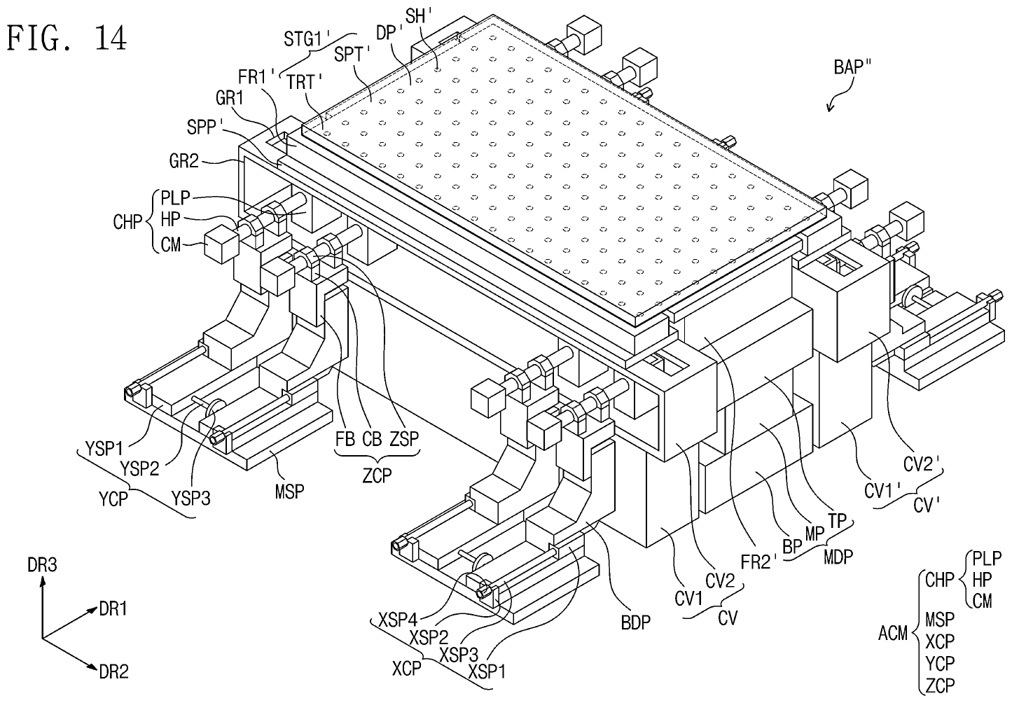

The panel fixing parts LDP may be spaced apart from each other in the second direction DR2. For example, although two panel fixing parts LDP are illustrated in FIG. 1, embodiments of the present disclosure are not limited thereto, and one or more panel fixing parts LDP may be disposed on corresponding motors SUM. The number of panel fixing parts LDP will be described in detail with reference to FIGS. 13 and 14.

The panel fixing parts LDP may include first stages STG1, supports SPP, first flat plate portions FR1, and second flat plate portions FR2. For example, each panel fixing part LDP may include a first stage STG1, a support SPP, a first flat plate portion FR1, and a second flat plate portion FR2.

The supports SPP may be disposed on the top surface of the second cover CV2. The supports SPP may overlap the first groove GR1. Although not shown, one or more grooves may be defined in top surfaces of the supports SPP. The grooves defined in the top surface of the supports SPP may overlap the first groove GR1 defined in the top surface of the second cover CV2.

Each first flat plate portion FR1 may be disposed on a corresponding support SPP. The first flat plate portions FR1 may overlap the second groove GR2. For example, when viewed in the first direction DR1, each of the first flat plate portions FR1 may have a rectangular shape. However, the shapes of the first flat plate portions FR1 are not limited thereto, and each of the first flat plate portions FR1 may have various shapes.

Each of the first flat plate portions FR1 may include quartz. The first flat plate portions FR1 may be transparent. In some aspects, light emitted from the alignment cameras ACM, which will be described later herein, may pass through the first flat plate portions FR1.

Each of the second flat plate portions FR2 may be disposed on a corresponding motor SUM of the motors SUM. Each first flat plate portion FR1 may be arranged with a corresponding second flat plate portion FR2 in the first direction DR1.

The second flat plate portions FR2 may be connected to the motors SUM. In an example, the second flat plate portions FR2 may be connected to the controller MDP through the motors SUM. Thus, when the upper controller TP and the middle controller MP move, the second flat plate portions FR2 may move in the same direction as the movement direction of the upper controller TP and the middle controller MP. The movement of the second flat plate portions FR2 will be described in detail with reference to FIGS. 11D to 11G.

Each of first stages STG1 may be disposed on a corresponding first flat plate portion FR1 and a corresponding second flat plate portion FR2. Each of the stages STG1 may overlap the corresponding first flat plate portion FR1 and second flat plate portion FR2.

Each of the first stages STG1 may have a plane defined by the first direction DR1 and the second direction DR2. For example, when viewed in the plan view, each of the first stages STG1 may have a rectangular shape having longer sides extending in the first direction DR1 and shorter sides extending in the second direction DR2. However, the embodiments of the present disclosure are not limited thereto, and each of the first stages STG1 may have a rectangular shape having shorter sides extending in the first direction DR1 and longer sides extending in the second direction DR2. The shapes of the first stages STG1 will be described in detail with reference to FIGS. 13 and 14.

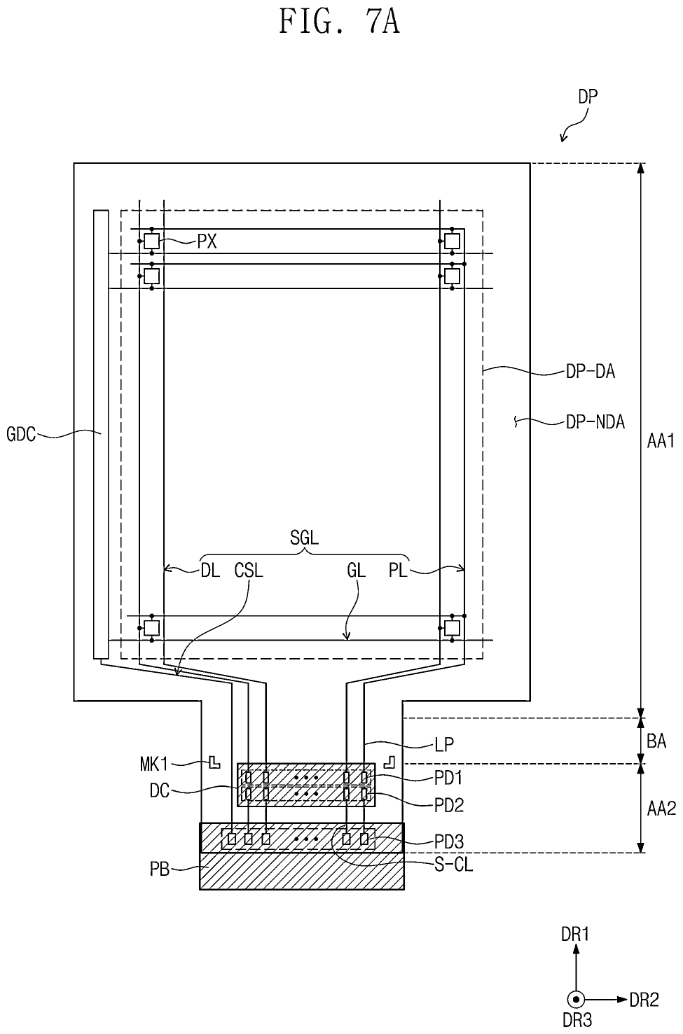

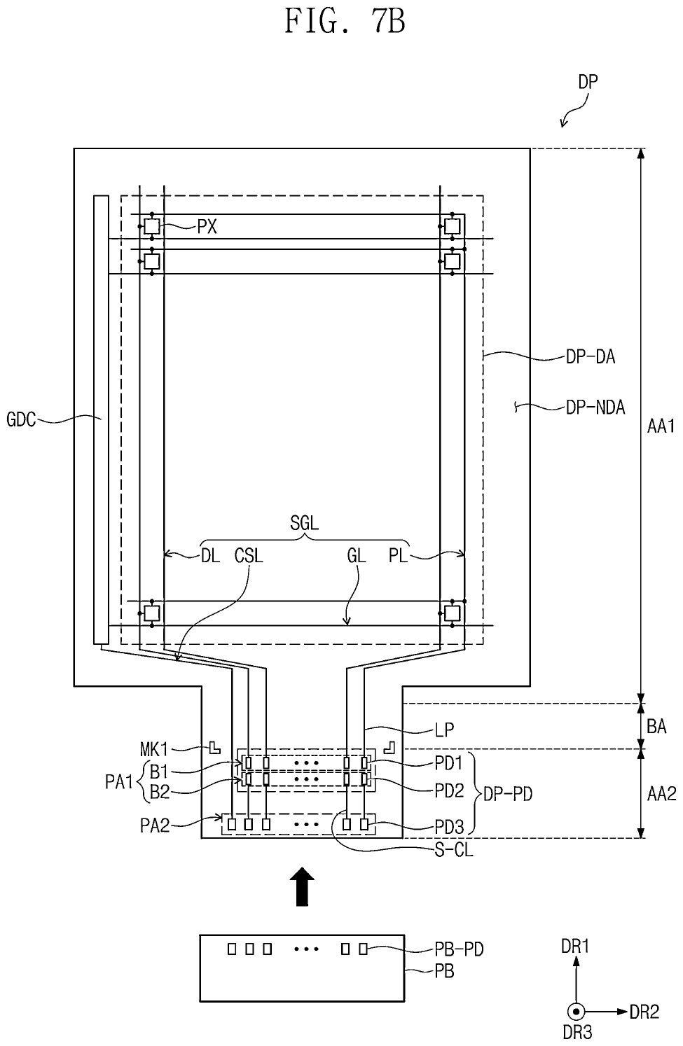

A display panel DP and a data driver DC (not illustrated at FIG. 1), which will be described with reference to FIGS. 7A and 7B, may be disposed on the first stages STG1. Example aspects of disposing the display panel and the data driver DC on the first stages STG1 will be described in detail with reference to FIGS. 11A to 11I.

Each of the first stages STG1 may include an adsorption part SPT and a transmission part TRT. The absorption parts SPT and transmission parts TRT may be arranged in the first direction DR1. Substantially, each adsorption part SPT may be integrated with a corresponding transmission parts TRT.

In an example, an adsorption part SPT may be disposed on a second flat plate portion FR2. The adsorption part SPT may overlap a motor SUM. The adsorption parts SPT may be connected to the motor SUM through a second flat plate portion FR2. Thus, when the upper controller TP and the middle controller MP move, the first stage STG1 may move in the same direction as the movement direction of the upper controller TP and the middle controller MP.

The plurality of adsorption holes SH may be defined in top surfaces of the adsorption parts SPT. The adsorption holes SH may be arranged in the first direction DR1 and the second direction DR2.

When viewed in the plan view, the adsorption holes SH may overlap the motors SUM. When viewed in the plan view, the adsorption holes SH may not overlap the first flat plate portions FR1. Although not shown, the adsorption holes SH may be connected to the motors SUM and converted into a vacuum state.

Each of the transmission parts TRT may extend in the first direction DR1 to overlap a corresponding first flat plate portion FR1. When viewed in the plan view, the transmission parts TRT may overlap the corresponding first flat plate portion FR1 and the first groove GR1.

Referring to FIGS. 1 and 3, the alignment cameras ACM may be arranged with the cover CV in the first direction DR1. The alignment cameras ACM may be disposed adjacent to one surface of the second cover CV. Hereinafter, for convenience of explanation, one alignment camera ACM will be described.

The alignment camera ACM may include imaging parts CHP, a main plate MSP, body parts BDP, and adjusting parts JOP. The imaging parts CHP and adjusting parts JOP may be disposed on a main plate MSP. The terms “adjusting parts” and “adjustment parts” may be used interchangeably herein.

In an example, when viewed in the plan view, the main plate MSP may have a hexahedral shape. In another example, when viewed in the plan view, the main plate MSP may have a rectangular shape. However, the embodiments of the present disclosure are not limited thereto, and the main plate MSP may have various shapes.

The adjusting parts JOP may include height adjusting parts ZCP, front-and-rear adjusting parts XCP, and left-and-right adjusting parts YCP. In the examples described herein, height adjustment may refer to movement along an axis corresponding to the third direction DR3, front-and-rear adjustment may refer to movement along an axis corresponding to the first direction DR1, and left-and-right adjustment may refer to movement along an axis corresponding to the second direction DR2. The front-and-rear adjusting parts XCP, the left-and-right adjusting parts YCP, the height adjusting parts ZCP, and the imaging parts CHP may be disposed on the main plate MSP.

The left-and-right adjusting parts YCP may be disposed on a top surface of the main plate MSP. The left-and-right adjusting parts YCP may include first left-and-right adjusting parts YSP1, a second left-and-right adjusting part YSP2, and a third left-and-right adjusting part YSP3.

The first left-and-right adjusting parts YSP1 may be disposed on the top surface of the main plate MSP. The first left-and-right adjusting parts YSP1 may be spaced apart from each other in the second direction DR2. Each of the first left-and-right adjusting parts YSP1 may have a rectangular parallelepiped shape.

The second left-and-right adjusting part YSP2 and the third left-and-right adjusting part YSP3 may be disposed between the first left-and-right adjusting parts YSP1. The second left-and-right adjusting part YSP2 may extend in the second direction DR2. Referring to sides of the second left-and-right adjusting part YSP2 opposing each other in the second direction DR2, one of the sides may be connected to a surface of a first left-and-right adjusting part YSP1, and another of the sides may be connected to a surface of the other first left- and right adjusting part YSP1. The surface of the first left-and-right adjusting part YSP1 and the surface of the other first left- and right adjusting part YSP1 to which the second left-and-right adjusting part YSP2 is connected may be defined as side surfaces facing each other.

According to one or more embodiments of the present disclosure, although not shown, gears may be disposed inside the first left-and-right adjusting parts YSP1, and gears may be disposed at opposite sides of the second left-and-right adjusting part YSP2 in the second direction DR2. The gears disposed at both sides of the second left-and-right adjusting part YSP2 may be engaged with the gears disposed inside the first left-and-right adjusting parts YSP1, and rotation of the engaged gears may support movement of the to rotate. Thus, when the second left-and-right adjusting part YSP2 rotate about a rotation axis parallel to the second direction DR2, the first left-and-right adjusting parts YSP1 may move in the second direction DR2.

The third left-and-right adjusting part YCP3 may be connected to the second left-and-right adjusting part YCP2. Although not shown, the second left-and-right adjusting part YCP2 may be disposed in an opening defined by the third left-and-right adjusting part YCP3. The second left-and-right adjusting part YCP2 may pass through the opening of the third left-and-right adjusting part YCP3.

The third left-and-right adjusting part YCP3 may rotate about the rotation axis parallel to the second direction DR2. When the third left-and-right adjusting part YCP3 rotates, the second left-and-right adjusting part YCP2 connected to the third left-and-right adjusting part YCP3 may rotate about the rotation axis parallel to the second direction DR2. When the second adjusting part YCP2 rotates, each of the first left-and-right adjusting parts YSP1 may move to a left or right side (e.g., the first left-and-right adjusting parts YSP1 may move in opposing directions of the second direction DR2). For example, the first left-and-right adjusting parts YSP1 may move such that a distance between the first left-and-right adjusting parts YSP1 in the second direction DR2 increases or decreases.

The body parts BDP may be disposed on top surfaces of the first left-and-right adjusting parts YSP1. The body parts BDP may be spaced apart from each other in the second direction DR2. Each of the body parts BDP may be disposed on a corresponding first left-and-right adjusting part YSP1 of the first left-and-right adjusting parts YSP1.

The body parts BDP may extend in the first and third directions DR1 and DR3. When viewed in the second direction DR2, each of the body parts BDP may have an ‘L’ shape symmetrical to the left and right (e.g., a dimension of a body part BDP in the first direction DR1 may be equal to a dimension of the body part BDP in the third direction DR3).

Each front-and-rear adjusting part XCP may be disposed on a corresponding first left-and-right adjusting part YSP1. The front-and-rear adjusting parts XCP may be disposed adjacent to the other sides of the first left-and-right adjusting parts YSP1 that are opposite to each other in the second direction DR2. Hereinafter, the other sides of the opposite sides of the first left-and-right adjusting parts YSP1 in the second direction DR2 may be defined as sides opposite to the sides facing each other.

Each of the front-and-rear adjusting parts XCP may include a first front-and-rear adjusting part XSP1, a second front-and-rear adjusting part XSP2, a third front-and-rear adjusting part XSP3, and a fourth front-and-rear adjusting part XSP4. The first to fourth front-and-rear adjusting parts XSP1 to XSP4 may be arranged in the first direction DR1.

The first front-and-rear adjusting parts XSP1 may be disposed on corresponding first left-and-right adjusting parts YSP1. Each of the first front-and-rear adjusting parts XSP1 may be disposed adjacent to one side of each of the body parts BDP (e.g., a side of a corresponding body part BDP). Each of the first front-and-rear adjusting parts XSP1 may be connected to one side of each of the body parts BDP (e.g., the side of the corresponding body part BDP). One sides of the body parts BDP may be defined as sides opposite to the other sides facing each other.

The second front-and-rear adjusting parts XSP2 may be disposed at first side surfaces of the first left-and-right adjusting parts YSP1, in which the first side surfaces are opposite to second side surfaces of the first left-and-right adjusting parts YSP1 in the first direction DR1. The first side surfaces of the first left-and-right adjusting parts YSP1 may be defined as side surfaces opposite to the second side surfaces adjacent to the body parts BDP. When viewed in the first direction DR1, the second front-and-rear adjusting parts XSP2 may be disposed adjacent to the other sides of the first left-and-right adjusting parts YSP1.

Shaft grooves SFG may be defined in top surfaces of the second front-and-rear adjusting parts XSP2. When viewed in the first direction DR1, each of the shaft grooves SFG may have a partial circular shape (e.g., a semi-circular shape).

The third front-and-rear adjusting parts XSP3 may respectively be disposed in the shaft grooves SFG. The third front-and-rear adjusting parts XSP3 may be disposed between the first front-and-rear adjusting parts XSP1 and the second front-and-rear adjusting parts XSP2.

Each of the third front-and-rear adjusting parts XSP3 may have a cylindrical shape extending in the first direction DR1. One sides of opposite sides of the third front-and-rear adjusting parts XSP3 in the first direction DR1 may be connected to the first front-and-rear adjusting part XSP1. Expressed another way, for a given third front-and-rear adjusting part XSP3 having opposite end portions in the first direction DR1, one end portion of the opposite end portions may be connected to a corresponding first front-and-rear adjusting part XSP1.

Although not shown, gears may be provided inside each of the first front-and-rear adjusting parts XSP1. Although not shown, each of the third front-and-rear adjusting parts XSP3 may include gears disposed at one sides (e.g., the opposite end portions). When a third front-and-rear adjusting part XSP3 rotates about the rotation axis parallel to the first direction DR1, the gears of a corresponding first front-and-rear adjusting part XSP1 and the gears of the third front-and-rear adjusting part XSP3 may be engaged with each other to rotate. Rotation of the engaged gears may result in reciprocated movement the first front-and-rear adjusting part XSP1 in the first direction DR1.

The other sides of opposite sides of the third front-and-rear adjusting parts XSP3 in the first direction DR1 may be disposed to rotate in the shaft grooves SFG defined in the second front and rear adjusting parts XSP2. Expressed another way, for each third front-and-rear adjusting part XSP3, the other end portion of the opposite end portions in the first direction DR1 may be disposed to rotate in a shaft groove SFG defined in a corresponding second front-and-rear adjusting part XSP2. One side of the opposite sides of the third front-and-rear adjusting parts XSP3 in the first direction DR1 may be defined as sides adjacent to the body parts BDP. Expressed another way, an end portion of the opposite end portions of the third front-and-rear adjusting parts XSP3 in the first direction DR1 (e.g., an end portion connected to a corresponding first front and rear adjusting part XSP1) may be defined as an end portion adjacent to the body parts BDP.

The fourth front-and-rear adjusting parts XSP4 may be coupled to the other sides (also referred to herein as end portions) of the third front-and-rear adjusting parts XSP3. The fourth front-and-rear adjusting parts XSP4 may be disposed at one sides of opposite sides of the second front-and-rear adjusting parts XSP2 in the first direction DR1. Expressed another way, a set of surfaces of a second front-and-rear adjusting part XSP2 may be oppositely facing along an axis parallel to the first direction DR1, and a corresponding fourth front-and-rear adjusting part XSP4 may be disposed on one of the oppositely facing surfaces. One sides of the opposite sides of the second front and rear adjusting parts XSP2 in the first direction DR1 may be defined as opposite sides to the other sides facing the first front-and-rear adjusting parts XSP1.

In an example, each of the fourth front-and-rear adjusting parts XSP4 may have a hexagonal prism shape, but the shapes of the fourth front-and-rear adjusting parts XSP4 are not limited thereto, and each of the fourth front-and-rear adjusting parts XSP4 may have various shapes.

When the fourth front-and-rear adjusting parts XSP4 rotate about the rotation axis parallel to the first direction DR1, the third front-and-rear adjusting parts XSP3 respectively connected to the fourth front-and-rear adjusting parts XSP4 may rotate about the rotation axis parallel to the first direction DR1.

When a third front-and-rear adjusting part XSP3 rotates, gears (not shown) disposed at the other end portion of the third front-and-rear adjusting part XSP3 and gears (not shown) disposed inside a corresponding first front-and-rear adjusting part XSP1 may be engaged with each other to rotate. Rotation of the engaged gears may result in reciprocated movement of the first front-and-rear adjusting part XSP1 in the first direction DR1. The body parts BDP may be closer to or farther from the cover CV. In an example, in response to rotation of the engaged gears, a body part BDP associated with the third front-and-rear adjusting part XSP3 and the first front-and-rear adjusting part XSP1 may move such that a distance between the body part BDP and the cover CV increases or decreases.

The height adjusting parts ZCP may be disposed on corresponding body parts BDP. The height adjusting parts ZCP may include adjusting portions ZSP, connection portions CB, and cover portions FB. The adjusting portions ZSP, the connection portions CB, and the cover portions FB may be connected to each other.

When viewed in the second direction DR2, each of the adjusting portions ZSP may have an ‘L’ shape upside down.

Each of the adjusting portions ZSP may include a first portion PT1 and a second portion PT2. When viewed in the second direction DR2, the first portions PT1 may extend in the third direction DR3. When viewed in the first direction DR1, each of the first portions PT1 may have a rectangular shape defined by the second and third directions DR2 and DR3.

The first portions PT1 may move in the third direction DR3 along the corresponding body parts BDP. As the first portions PT1 move in the third direction DR3, the first portions PT1 may be closer to or farther from the main plate MSP.

The second portions PT2 may extend from upper ends of the first portions PT1 in the first direction DR1. When viewed in the plan view, each of the second portions PT2 may have a rectangular shape defined by the first and second directions DR1 and DR2.

Substantially, the first portions PT1 and the second portions PT2 may be integrated with each other. Thus, when the first portions PT1 move in the third direction DR3 along the body parts BDP, the second portions PT2 may move in the third direction DR3.

The plurality of connection portions CB and the plurality of cover portions FB may be disposed on top surfaces of corresponding second portions PT2. In an example, for a given height adjusting part ZCP, the connection portions CB may be arranged in the first direction DR1. When viewed in the plan view, the connection portions CB may be disposed adjacent to opposite sides of the second portions PT2 in the first direction DR1.

As the connection portions CB are connected to the corresponding adjusting portions ZSP, when an adjusting portion ZSP moves in the third direction DR3, the corresponding connection portions CB move in the third direction DR3.

A first barrel groove HPG1 may be defined in a top surface of each of the connection portions CB. Each of the first barrel grooves HPG1 may have a downwardly concave semicircular shape.

Each of the cover portions FB may be disposed on a corresponding connection portion CB of the connection portions CB. The cover portions FB may be connected to the connection portions CP. The cover portions FB may be connected to the adjusting portions ZSP via the connection portions CP. Thus, when an adjusting portion ZSP moves in the third direction DR3, corresponding cover portions FB may move in the third direction DR3.

When viewed in the first direction DR1, an edge of each of the cover portions FB may have a partial hexagonal shape. A second barrel grooves HPG2 may be defined in each of the cover portions FB. When viewed in the first direction DR1, each of the second barrel grooves HPG2 may have an upwardly convex semicircular shape. Barrels HP to be described later herein may be disposed in the first and second barrel grooves HPG1 and HPG2.

The imaging parts CHP may be disposed on corresponding height adjusting parts ZCP. Portions (e.g., barrel parts HP) of the imaging parts CHP may be disposed in the first and second barrel grooves HPG1 and HPG2. The imaging parts CHP (e.g., at a barrel part HP) may be coupled to corresponding connection portions CB and cover portions FB. Each imaging part CHP may be connected to corresponding height adjusting parts ZCP, body parts BDP, left-and-right adjusting parts YCP, and front-and-rear adjusting parts XCP.

Each of the imaging parts CHP may include a camera CM, a barrel part HP, and a spectrum part PLP. The camera CM, the barrel part HP, and the spectrum part PLP may be arranged in the first direction DR1.

The spectrum parts PLP may be disposed in the second groove GR2 defined in the second cover CV2. The spectrum parts PLP may overlap the first groove GR1. Each of the spectrum parts PLP may overlap a corresponding support SPP and a corresponding first flat plate portion FR1. Each first flat plate portion FR1 may be disposed on one or more spectrum parts PLP. The spectrum parts PLP may overlap the transmission parts TRT.

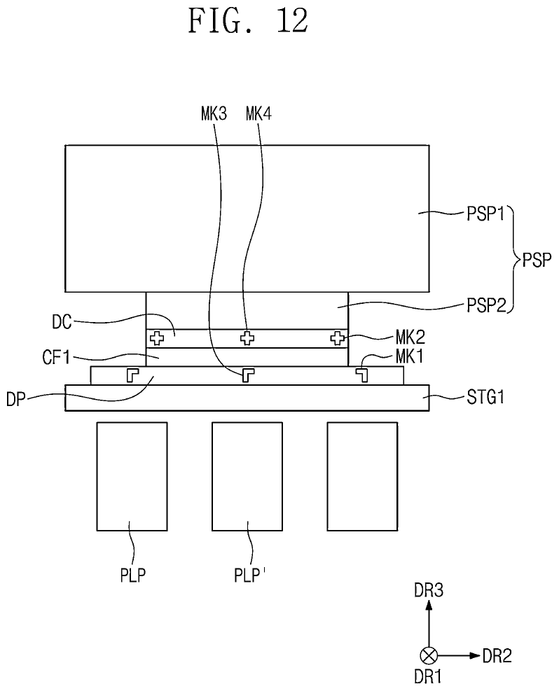

The spectrum parts PLP may be arranged in the second groove GR2 in the second direction DR2. For example, two spectrum parts PLP are disposed below each of the first flat plate portions FR1, but the present disclosure is not limited thereto, and one spectrum PLP or three or more spectrum parts PLP may be disposed below each of the first flat plate portions FR1. A description of the spectrum parts PLP will be described in detail with reference to FIG. 12.

In an example, the spectrum parts PLP may have a partial hexahedral shape. When viewed in the plan view, each of top surfaces of the spectrum parts PLP may have a frame shape.

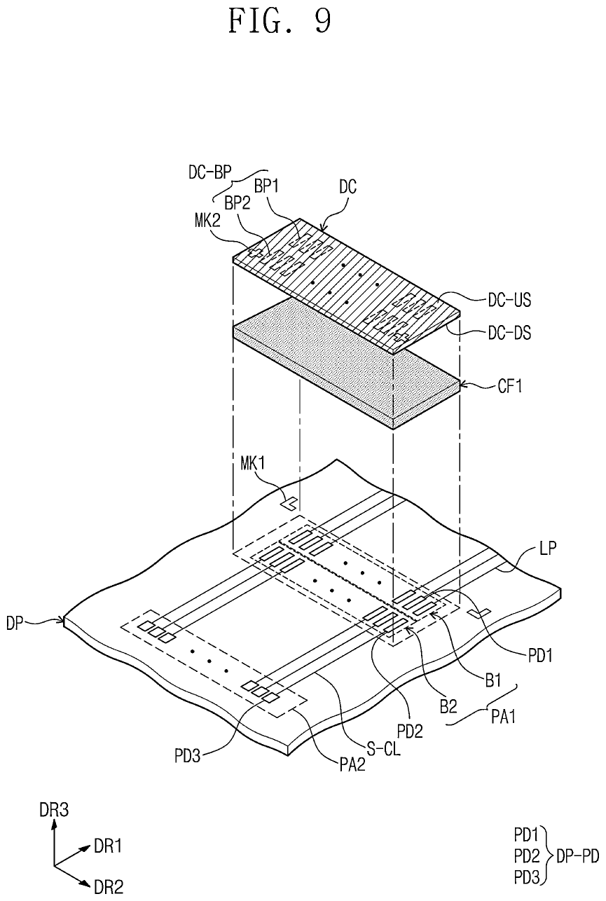

Although not shown, the spectrum parts PLP may include lighting devices and prism lenses therein. Although not shown, when the lighting devices of the spectrum parts PLP emit light toward the prism lenses, the prism lenses may disperse the light into a spectrum. Thus, the dispersed light may pass through the first flat plate portions FR1 and then be emitted toward the display panel DP (see FIG. 7) and the data driver DC (see FIGS. 7A and 9) disposed on the first stage STG1, example aspects of which will be explained in detail with reference to FIGS. 11D to 11H.

The barrel parts HP may be disposed on the connection portions CB. The barrel parts HP may be disposed in the first barrel grooves HPG1 defined in the connection portions CB. The barrel parts HP may be disposed below the cover portions FB. The barrel parts HP may be disposed in the second barrel grooves HPG2 defined in the cover portions FB.

The barrel parts HP may be surrounded by the connection portions CB and the cover portions FB. The barrel parts HP may be connected to the body parts BDP by the connection portions CB and the cover portions FB. The barrel parts HP may be connected to the height adjusting parts ZCP, the left-and-right adjusting parts YCP, and the front-and-rear adjusting parts XCP. It is to be understood that descriptions referencing a plurality of a given component (e.g., barrel parts HP) in relation to other components (e.g., connection portions CB and the cover portions FB) may refer to a singular instance of the given component and corresponding singular instances of the other components.

The barrel parts HP may extend in the first direction DR1. For example, each of the barrel parts HP may have a cylindrical shape. However, the embodiment of the present disclosure is not limited thereto, and the shapes of the barrel parts HP may vary.

Each of the barrel parts HP may be connected to a corresponding spectrum part PLP of the spectrum parts PLP. One sides of the opposite sides of the barrel parts HP in the first direction DR1 may be connected to the spectrum parts PLP. One sides of the barrel parts HP may be defined as sides adjacent to the cover CV. Expressed another way, for a given barrel part HP, an end portion of the barrel part HP (of opposite end portions in the first direction DR1) may be connected to a corresponding spectrum part PLP. The end portions of the barrel parts HP, connected to respective corresponding spectrum parts PLP, may be defined as end portions adjacent to the cover CV. The terms “end portion” and “end side” of the barrel part HP may be used interchangeably herein.

The cameras CM may be connected to the other sides of the opposite sides of the barrel parts HP in the first direction DR1. Expressed another way, the cameras CM may be connected to the other end portions of the opposite end portions of the barrel parts HP in the first direction DR1. Each of the cameras CM may be connected to a corresponding barrel part HP of the barrel parts HP.

The cameras CM may capture images formed on the spectrum parts PLP. For example, the cameras CM may include a near infrared (NIR) camera and a charge-coupled device camera (CCD). Light reflected from the display panel DP (see FIG. 7A) and the data driver DC (see FIGS. 7A and 9) may be incident to the cameras CM through prism lenses disposed inside the spectrum parts PLP, example aspects of which will be explained in detail with reference to FIGS. 11E to 11H.

For example, in FIGS. 1 and 3, one left-and-right adjusting part YCP, two front-and-rear adjusting parts XCP, two body parts BDP, and two height adjustment parts ZCP, and two imaging parts CHP are disposed on one main plate MSP, but example embodiments of the present disclosure are not limited thereto. For example, three imaging parts CHP may be disposed on one main plate MSP, an example of which will be detailed with reference to FIG. 12.

The plurality of preliminary stages YST may be disposed at opposite sides of the alignment cameras ACM facing each other in the first direction DR1. The preliminary stages YST may be arranged with the alignment cameras ACM in the first direction DR1.

In an example, the number of preliminary stages YST and the number of alignment cameras ACM may be equal. However, the embodiments of the present disclosure are not limited thereto, and the number of preliminary stages YST and the number of alignment cameras ACM may be different.

The preliminary stages YST may include drivers PST and second stages STG2. Each of the second stages STG2 may be disposed on a corresponding driver PST of the drivers PST. Each of the second stages STG2 may be connected to a corresponding driver PST of the drivers PST.

The driver PST may include bottom parts BAT, supports DAR, and flat plate parts HPT. Hereinafter, for convenience of description, any one of the bottom part BAT, the support part DAR, and the flat plate part HPT will be described.

The bottom part BAT may have a disk shape. When viewed in the plan view, the bottom part BAT may have a circular shape.

The support part DAR may be disposed on the bottom part BAT. The support part DAR may be rotatably coupled to the bottom part BAT. The support part DAR may rotate about a rotation axis parallel to the third direction DR3.

The support part DAR may extend in the third direction DR3. For example, the support part DAR may have a cylindrical shape.

The flat plate part HPT may be disposed on the support part DAR. The flat plate part HPT may be connected to the support part DAR. Thus, when the support part DAR rotates about the rotation axis parallel to the third direction DR3, the flat plate part HPT may rotate about the rotation axis parallel to the third direction DR3.

In an example, when viewed in the plan view, the flat plate part HPT may have a rectangular shape having longer sides extending in the first direction DR1 and shorter sides extending in the second direction DR2. However, the shape of the flat plate part HPT is not limited thereto, and the flat plate part HPT may have various shapes.

The second stage STG2 may be disposed on the driver PST. The second stage STG2 may be disposed on a top surface of the flat plate part HPT. The second stage STG2 may be disposed adjacent to one side of opposite sides of the flat plate part HPT in the first direction DR1. For example, it is illustrated that one second stage STG2 is disposed on the top surface of the flat plate part HPT, but example embodiments of the present disclosure are not limited thereto. The plurality of second stages STG2 may be disposed on opposite sides of the flat plate part HPT in the first direction DR1. One side of the opposite sides of the flat plate part HPT in the first direction DR1 may be defined as a side opposite to the other side facing the alignment cameras ACM.

The second stage STG2 may be connected to the support part DAR by the flat plate part HPT. Thus, when the support part DAR rotates around the rotation axis parallel to the third direction DR3, the second stages STG2 may rotate around the rotation axis parallel to the third direction DR3 to move. The second stage STG2 may move to be adjacent to the alignment cameras ACM. For example, FIG. 1 illustrates a state before the flat plate part HPT rotates.

When viewed in the plan view, the second stage STG2 may have a rectangular shape. For example, when viewed in the plan view, the second stage STG2 may have a rectangular shape having longer sides extending in the first direction DR1 and shorter sides extending in the second direction DR2. However, it is not limited thereto, and the second stage STG2 may have other various shapes (e.g., a circular shape, a triangular shape). When viewed in the plan view, an area of the second stage STG2 may be less than an area of the flat plate part HPT.

A third groove GR3 may be defined in a top surface of the second stage STG2. When viewed in the plan view, the third groove GR3 may have shorter sides extending in the first direction DR1 and longer sides extending in the second direction DR2. When viewed in the plan view, the third groove GR3 may have a rectangular shape.

The third groove GR3 may accommodate data drivers DC to be described with reference to FIG. 9. Example aspects of accommodating the data drivers DC will be explained in detail with reference to FIG. 11A.

First camera parts CMP1 may be disposed on corresponding second stages STG2 and drivers PST. The first camera parts CMP1 may capture images of the data drivers DC (see FIG. 9) accommodated in the third grooves GR3. The imaging of the first camera parts CMP1 will be described in detail with reference to FIG. 11A.

Pressing parts PSP may be disposed on corresponding second stages STG2 and drivers PST. When a flat plate part HPT rotates, the second stage STG2 may be disposed below a corresponding pressing part PSP. The pressing parts PSP are disposed above (e.g., higher than) the first and second stages STG1 and STG2, such that the pressing parts PSP may adsorb the data drivers DC disposed in the third grooves GR3 (see FIG. 9) to transfer the data drivers DC onto the first stages STG1. The pressing parts PSP may provide data drivers DC (see FIG. 9) on the first stages STG1. In an example of adsorbing data drivers DC, the pressing parts PSP may press the data drivers DC (see FIG. 9) disposed on the display panel DP. In an example, a pressing part PSP is capable of applying pressure in the third direction DR3 to a data driver DC in association with transferring or adhering the data driver DC to a corresponding first stage STG1. Example aspects of pressing the data drivers DC disposed on the display panel DP will be explained in detail with reference to FIGS. 11F to 11H.

Second camera parts CMP2 may be disposed below the second stages STG2 and the drivers PST. When the second stages STG2 are disposed below the pressing parts PSP, the second camera parts CMP2 may capture images of the data drivers DC (see FIG. 9) accommodated in the third grooves GR3. The imaging of the second camera parts CMP2 will be described in detail with reference to FIGS. 11B and 11C.

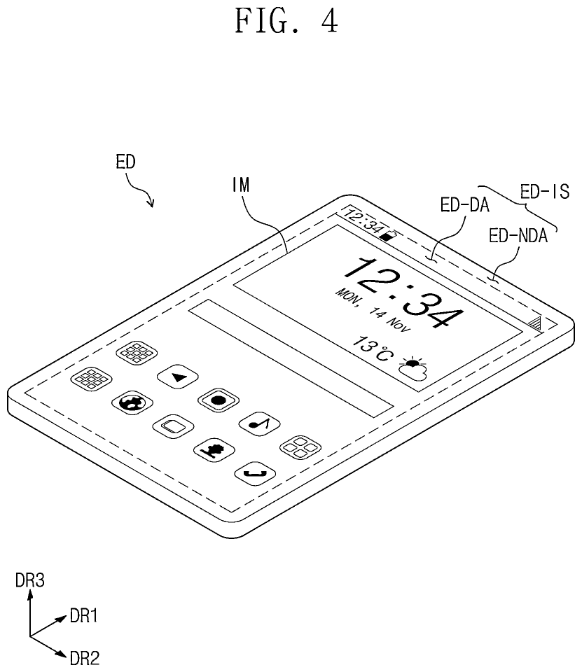

FIG. 4 is a perspective view of an embodiment of an electronic apparatus including a display panel manufactured using the bonding apparatus of FIG. 1.

Referring to FIG. 4, the electronic apparatus ED may have a rectangular shape having longer sides extending in the first direction DR1 and shorter sides extending in the second direction DR2. However, the example embodiments of the present disclosure are not limited thereto. For example, the electronic apparatus ED may have other various shapes (e.g., a circular shape, a polygonal shape, and the like).

A top surface of the electronic apparatus ED may be defined as a display surface ED-IS, and the display surface ED-IS may have a plane defined by the first and second directions DR1 and DR2. Images IM generated by the electronic apparatus ED 9ED may be provided to a user through the display surface ED-IS.

The display surface ED-IS may include a display area ED-DA and a non-display area ED-NDA surrounding the display area ED-DA. The display area ED-DA may display an image, and the non-display area ED-NDA may not display an image. The non-display area ED-NDA may surround the display area ED-DA and define an edge of the electronic apparatus ED, which is printed with a predetermined color.

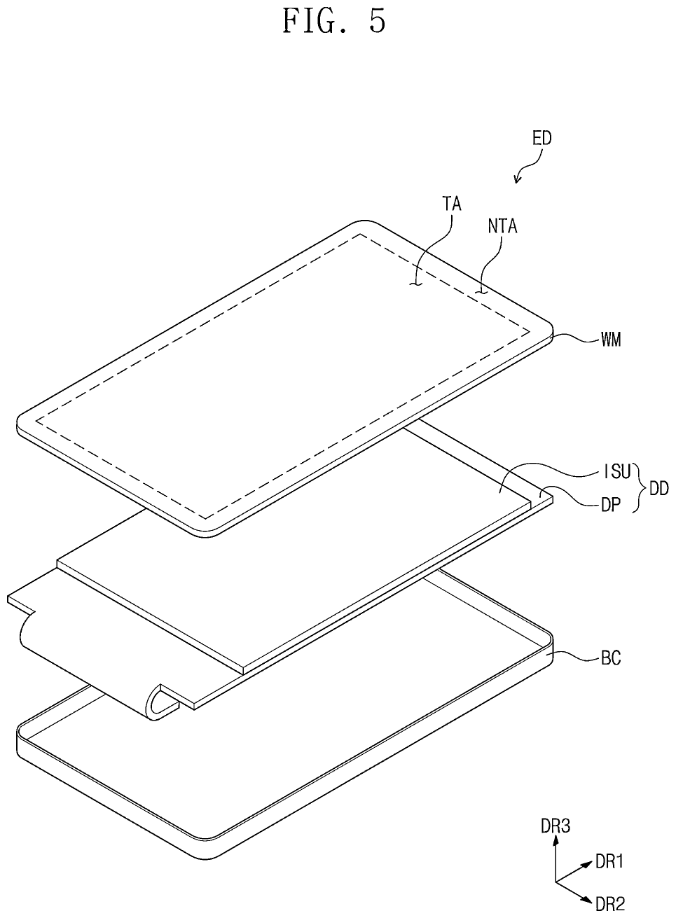

FIG. 5 is an exploded perspective view of an embodiment of the electronic apparatus of FIG. 4.

Referring to FIG. 5, the electronic apparatus ED may include a window WM, a display device DD, and a housing BC. The housing BC may accommodate the display device DD and may be coupled to the window WM. Although not shown, the electronic apparatus ED may further include other electronic modules accommodated in the housing BC and electrically connected to the display panel DP. For example, the electronic apparatus ED may further include a main board, a circuit module mounted on the main board, a camera module, and a power module.

The window WM may be disposed above the display device DD. The window WM may transmit an image provided from the display device DD to the outside. It is to be understood that references to signals, images, data, and the like transmitted to or received from “the outside” may include transmissions to electronic circuitry different from the elements described herein. The window WM may include a transmission area TA and a non-transmission area NTA. The transmission area TA may overlap the display area ED-DA of FIG. 4. The transmission area TA may have a shape corresponding to the display area ED-DA.

The non-transmission area NTA may overlap the non-display area ED-NDA and have a shape corresponding to the non-display area ED-NDA. The non-transmission area NTA may be an area having a light transmittance that is relatively less than the light transmittance of the transmission area TA.

The display device DD may be capable of generating an image and sensing an external input. The display device DD may include a display panel DP and an input sensor ISU. Although not shown, the display device DD may include a driver DC and a circuit board PB. The driver DC and the circuit board PB will be described with reference to FIGS. 7A and 9. Although not shown, the display device DD may further include an antireflection member disposed on the input sensor ISU. The antireflection member may include a polarizer and a retarder or may include a color filter and a black matrix.

The display panel DP may be an emission-type display panel, and the types of display panel DP are not limited to the examples described herein. In some examples, the display panel DP may be an organic light emitting display panel or an inorganic light emitting display panel. A light emitting layer of the organic light emitting display panel may include an organic light emitting material. An emission layer of the inorganic light emitting display panel may include quantum dots, quantum rods, nano LEDs, and the like. The terms “display panel DP” and “organic light emitting display panel” may be used interchangeably herein.

The input sensor ISU may include one of a capacitive sensor, an optical sensor, an ultrasonic sensor, and an electromagnetic induction sensor. The input sensor ISU may be formed on the display panel DP through a continuous process or may be separately manufactured and then attached to an upper side of the display panel DP through an adhesive layer.

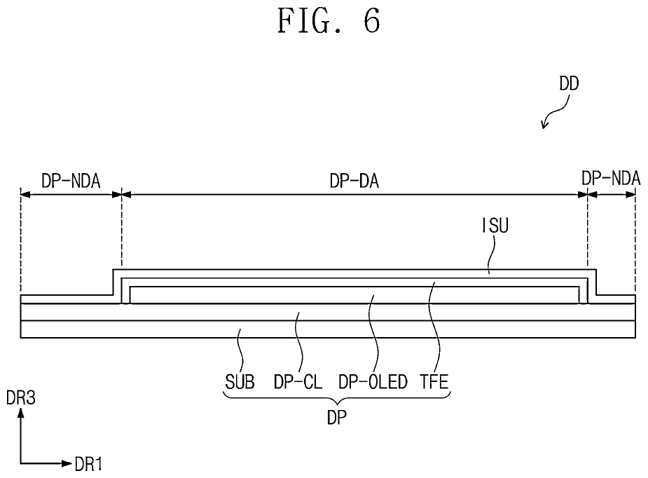

FIG. 6 is a cross-sectional view of an embodiment of the display device DD of FIG. 5.

Referring to FIG. 6, the display panel DP includes a substrate SUB, a circuit element layer DP-CL disposed on the substrate SUB, a display element layer DP-OLED, and a thin film encapsulation layer TFE. The input sensor ISU may be disposed on the thin film encapsulation layer TFE.

The substrate SUB may include a display area DP-DA and a non-display area DP-NDA around the display area DP-DA. The substrate SUB may include glass or a flexible plastic material (e.g., polyimide (PI)). The display element layer DP-OLED may be disposed on the display area DP-DA.

A plurality of pixels (not illustrated) may be disposed on the circuit element layer DP-CL and the display element layer DP-OLED. Although not shown, each of the pixels may include a plurality of transistors disposed on the circuit element layer DP-CL, at least one capacitor, and a light emitting element disposed on the display element layer DP-OLED and connected to the transistor.

The thin film encapsulation layer TFE may be disposed on the circuit element layer DP-CL to cover the display element layer DP-OLED. The thin film encapsulation layer TFE may protect the pixels from moisture, oxygen, and external foreign substances.

FIGS. 7A and 7B are plan views of an embodiment of the display panel of FIG. 6.

For example, FIG. 7B is a cross-sectional view of the display panel DP in which the data driver DC and circuit board PB of FIG. 7A are separated from each other.

Referring to FIGS. 7A and 7B, the display device DD may include a display panel DP, a data driver DC, and a circuit board PB. The display panel DP may include a plurality of pixels PX, a gate driving circuit GDC, a plurality of signal lines SGL, and a plurality of signal pads DP-PD.

The display panel DP may be a flexible display panel. For example, the display panel DP may include a plurality of electronic elements disposed on a flexible substrate. The display panel DP may extend longer in the first direction DR1 than in the second direction DR2. The display panel DP may have a plane defined by the first and second directions DR1 and DR2.

The display panel DP may include a first area AA1, a second area AA2, and a bending area BA disposed between the first area AA1 and the second area AA2. The bending area BA extends in the second direction DR2, and the first area AA1, the bending area BA, and the second area AA2 may be arranged in the first direction DR1.

With reference to the first area AA1, longer sides of the first area AA1 extend in the first direction DR1 and are opposite to each other in the second direction DR2. A length of each of the bending area BA and the second area AA2 in the second direction DR2 may be less than the length of the first area AA1.

The first area AA1 may include a display area DP-DA and a non-display area DP-NDA surrounding the display area DP-DA. The non-display area DP-NDA may surround the display area DP-DA. The display panel DP may display an image on the display area DP-DA but not on the non-display area DP-NDA. The second area AA2 and the bending area BA may be areas on which the display panel DP does not display an image.

The pixels PX may be disposed in the display area DP-DA. Each of the pixels PX includes an organic light emitting element and a pixel driving circuit connected thereto. The gate driving circuit GDC sequentially outputs gate signals to be described below to the plurality of gate lines GL. The transistor of the gate driving circuit GDC may be formed through the same process as the transistor of the pixel PX, for example, a low temperature polycrystalline silicon (LTPS) process or a low temperature polycrystalline oxide (LTPO) process. The display panel DP may further include another driving circuit that provides emission control signals to the pixels PX.

The signal lines SGL include gate lines GL, data lines DL, a power line PL, and a control signal line CSL. The gate lines GL are respectively connected to corresponding pixels of the pixels PX, and the data lines DL are respectively connected to corresponding pixels PX of the pixels PX. The power line PL may be connected to the pixels PX. The control signal line CSL may provide control signals to the scan driving circuit.

The signal lines SGL may overlap the display area DP-DA and the non-display area DP-NDA. Each of the signal lines SGL may include a line part LP. Although not shown, the signal lines SGL may further include pad parts (also referred to herein as “signal pads” or “pads”). The line part LP may overlap the display area DP-DA and the non-display area DP-NDA. The pad part may be connected to an end of the line part LP. The pad part may be connected to signal pads DP-PD to be described later.

Referring to FIG. 7A, the data driver DC and the circuit board PB may be mounted on the display panel DP. The data driver DC and the circuit board PB may be mounted on the second area AA2. The data driver DC may generate a driving signal associated with an operation of the display panel DP based on a control signal transmitted from the circuit board PB.

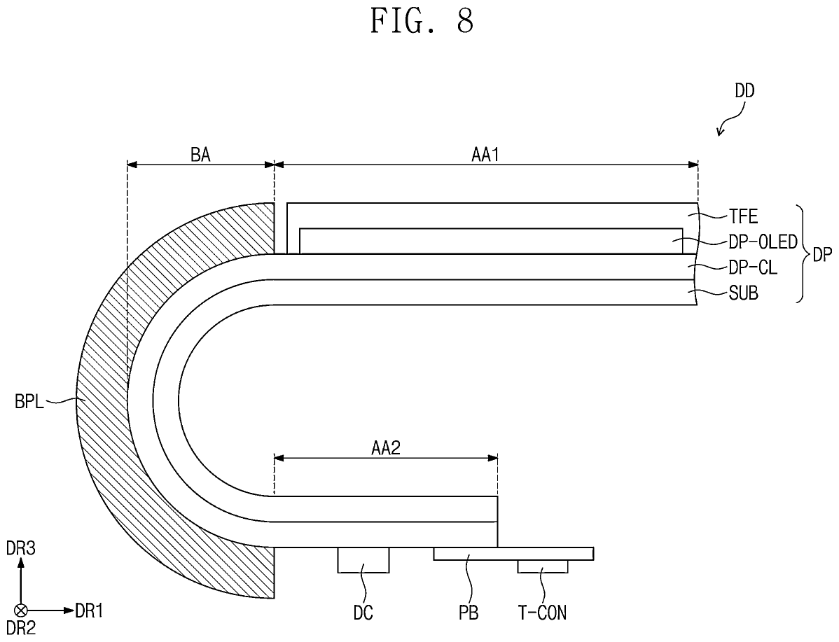

The circuit board PB may be electrically connected to the circuit element layer DP-CL of FIG. 6. Although not shown, the circuit board PB bonded to the display panel DP may be bent and disposed on a rear surface of the display panel DP, example aspects of which will be explained in detail with reference to FIG. 8.

The display panel DP may include a plurality of first marks MK1. In an example, although two first marks MK1 are illustrated in FIG. 7A, the number of first marks MK1 is not limited thereto. The first marks MK1 may at least partially overlap a boundary between the bending area BA and the second area AA2. However, the embodiments of the present disclosure are not limited thereto, and the first marks MK1 may be disposed in the bending area BA or the second area AA2, without overlapping the bending area BA and the second area AA2.

The first marks MK1 may be disposed at both sides of the display panel DP, which are opposite to each other in the second direction DR2. The first marks MK1 may be spaced apart from each other in the second direction DR2. The first marks MK1 may be symmetrical to each other in the second direction DR2.

The first marks MK1 may be disposed adjacent to the data driver DC. The first marks MK1 may be respectively disposed adjacent to both sides of the data driver DC, which are opposite to each other in the second direction DR2. The data driver DC may be disposed between the first marks MK1. For example, in the case of two first marks MK1, a distance from the data driver DC to one first mark MK1 may be equal to the distance from the data driver DC to the other first mark MK1.

In one or more embodiments, the first marks MK1 may have an ‘L’ shape. For example, when viewed in the plan view, a first mark MK1 of the two first marks MK1 is disposed at a left side of the display panel DP and may have an ‘L’ shape. The first mark MK1 disposed at a right side of the display panel DP may have a shape that is obtained by inverting the ‘L’ shape to left and right (e.g., mirroring the ‘L’ shape about an axis corresponding to the first direction DR1). However, the embodiments of the present disclosure are not limited thereto, and the shapes of the first marks MK1 may vary.

Referring to FIG. 7B, the plurality of signal pads DP-PD may include first pads PD1, second pads PD2, and third pads PD3. The area on which the first and second pads PD1 and PD2 are disposed may be defined as a first pad area PA1, and the area on which the third pads PD3 are disposed may be defined as a second pad area PA2.

The first pad area PA1 may be an area overlapping the data driver DC of FIG. 7A, and the second pad area PA2 may be an area overlapping the circuit board PB. The first pad area PA1 may include a first area B1 on which the first pads PD1 are disposed and a second area B2 on which the second pads PD2 are disposed. The first pad area PA1 and the second pad area PA2 may be disposed inside the non-display area DP-NDA. The first pad area PA1 and the second pad area PA2 may be spaced apart from each other in the first direction DR1.

Each of the first pads PD1 may be connected to a corresponding data line DL of the data lines DL. Although not shown, the first pads PD1 and the second pads PD2 may be electrically connected to each other. The second pads PD2 may be connected to the third pads PD3 through a connection signal lines S-CL.

The circuit board PB may include a plurality of circuit pads PB-PD. The circuit pads PB-PD may be arranged in the second direction DR2. The circuit pads PB-PD of the circuit board PB may be in contact with and be connected to the third pads PD3 of the second pad area PA2.

FIG. 8 is a view illustrating an example of a bent state of the bending area of FIGS. 7A and 7B. The terms “bent state” and “folded state” may be used interchangeably herein.

For example, FIG. 8 illustrates a side view of the display device DD when viewed in the second direction DR2.

A substrate SUB, a circuit element layer DP-CL, a display element layer DP-OLED, and a thin film encapsulation layer TFE of FIG. 8 may be the same as the substrate SUB, the circuit element layer DP-CL, the display element layer DP-OLED, and the thin film encapsulation layer (TFE) of FIG. 6, and a data driver DC and a circuit board PB may be the same as the data driver DC and the circuit board PB of FIGS. 7A and 7B, and thus duplicate descriptions thereof will be omitted or simplified.

The display device DD may include a bending protection layer BPL and a timing controller T-CON. The bending area BA may be bent such that the second area AA2 is disposed below the first area AAT. The circuit board PB bonded to the display panel DP may be bent and disposed on the rear surface of the display panel DP. Thus, the data driver DC, the circuit board PB, and the timing controller T-CON may be disposed below the second area AA2.

The bending protection layer BPL may be disposed on the bending area BA. The bending protection layer BPL may be adjacent to edges of the first and second areas AAT and AA2. The bending protection layer BPL may be disposed to be spaced apart from the thin film encapsulation layer TFE in the first direction DR1. When the display panel DP is bent, the bending protection layer BPL may be bent together with the bending area BA.

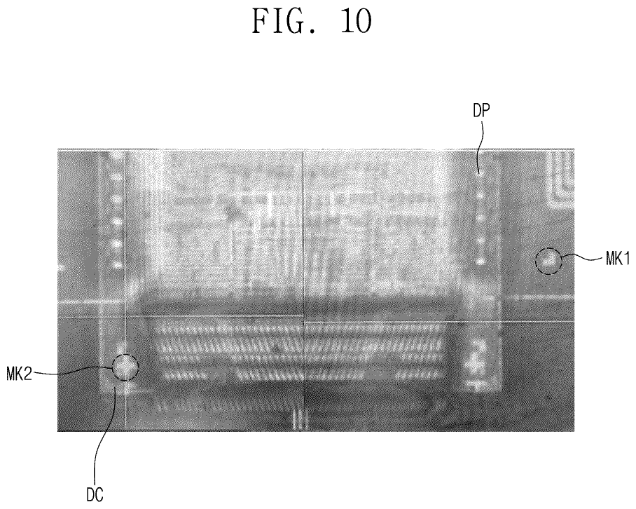

FIG. 9 is an enlarged perspective view of an embodiment of the pad areas PA1 and PA2 of FIGS. 7A and 7B. FIG. 10 is a view obtained by imaging the data driver DC and the display panel DP of FIG. 9 using an embodiment of imaging parts CHP of FIG. 1.

In some examples, the data driver DC of FIG. 9 may be disassembled from the display panel DP.

For example, FIG. 10 is an enlarged plan view of portions of the data driver DC and the display panel DP.

For example, in FIG. 9, the circuit board PB is omitted.

First pads PD1, second pads PD2, a connection signal line S-CL, line parts LP, and third pads PD3 of FIG. 9 may be the same as the first pads PD1, the second pads PD2, the connection signal line S-CL, the line parts LP, and the third pads PD3 of the FIG. 7B, and thus, duplicate descriptions thereof will be omitted or simplified.

Referring to FIGS. 7B and 9, the data driver DC may be disposed on the first and second pads PD1 and PD2. The data driver DC may include a top surface DP-US and a bottom surface DC-DS. The bottom surface DC-DS of the data driver DC may be a surface facing the first and second pads PD1 and PD2.

The data driver DC may include bump electrodes DC-BP electrically connected to the first pads PD1 disposed on the substrate SUB. The data driver DC may include bump electrodes DC-BP electrically connected to the first pads PD1 disposed on the substrate SUB. The bump electrodes DC-BP may include first bumps BP1 and second bumps BP2. The first bumps BP1 and the second bumps BP2 may be spaced apart from each other in the first direction DR1. The first bumps BP1 may be arranged in the second direction DR2. The second bumps BP2 may be arranged in the second direction DR2. Although not shown, the first bumps BP1 and the second bumps BP2 may protrude from the bottom surface DC-DS of the data driver DC and be exposed to the outside.

The data driver DC may include a plurality of second marks MK2. In some aspects, although two second marks MK2 are illustrated in FIG. 9, the number of second marks MK2 is not limited thereto.

The second marks MK2 may be spaced apart from each other in the second direction DR2. The second marks MK2 may be disposed on both sides of the data driver DC, which are opposite to each other in the second direction DR2. Expressed another way, the second marks MK2 may be respectively disposed at opposite sides of the data driver DC.

For example, the second marks MK2 may be disposed adjacent to one side of opposite sides of the data driver DC in the first direction DR1. One side of the data driver DC may be defined as a side facing the circuit board PB. Expressed another way, the surface of the data driver DC on which the second marks MK2 are disposed may be defined as a surface facing the circuit board PB.

In some examples, each of the second marks MK2 may have a cross shape. However, the embodiments of the present disclosure are not limited thereto, and the shapes of the second marks MK2 may vary.

Although not shown, the data driver DC may include an integrated circuit. The integrated circuit may be disposed on the bump electrodes DC-BP. The integrated circuit may be connected to the bump electrodes DC-BP. The data driver DC may receive first signals from the outside through second pads PD2 and second bumps BP2. The data driver DC may provide second signals generated based on the signals to the first pads PD1 through the first bumps BP1. The first signal may be an image signal that is a digital signal applied from the outside, and the second signal may be a data signal that is an analog signal. The data driver DC may generate an analog voltage corresponding to a grayscale value of the image signal. The data signal may be provided to the pixel PX through the data line DL illustrated in FIGS. 7A and 7B.

Referring to FIGS. 9 and 10, the data driver DC may adhere to the first pad area PA1 through the first adhesive layer CF1. Although not shown, the circuit board PB may be adhered to the second pad area PA2 through an adhesive layer of the same type as a first adhesive layer CF1. The first adhesive layer CF1 may include an adhesive synthetic resin.

Aspects of the present disclosure support aligning the data driver DC with the first adhesive layer CF1 and the first pad area PA1 in association with disposing the first adhesive layer CF1 on the first pad area PA1. For example, when the first adhesive layer CF1 is disposed on the first pad area PA1, the data driver DC may be aligned. Specifically, centers of the first marks MK1 may be aligned to match centers of the second marks MK2. The alignment of the data driver DC will be described in detail with reference to FIGS. 11D, 11F, and 11G.

According to one or more embodiments of the present disclosure, after aligning the data driver DC with the first adhesive layer CF1, the techniques described herein include moving the data driver DC in the third direction DR3 such that the data driver DC contacts a top surface of the first adhesive layer CF1. The data driver DC may be connected to the display panel DP through the first adhesive layer CF1. Specifically, the first bumps BP1 may be in contact with and electrically connected to the first pads PD1, and the second bumps BP2 may be in contact with and electrically connected to the second pads PD2.

When the first and second bumps BP1 and BP2 are connected to the first and second pads PD1 and PD2, the techniques described herein include further aligning the data driver DC with the first pad area PA1 (e.g., using first marks MK1 and second marks MK2) to compensate for errors in a process. Specifically, when the data driver DC moves in the third direction DR3, an error may occur in the process. For this, the techniques described herein include aligning a center between the first marks MK1 and a center between the second marks MK2 in the first direction DR1. The alignment after the movement of the data driver DC will be described in detail with reference to FIGS. 11E to 11F.

After aligning the data driver DC with the first adhesive layer CF1 (e.g., within a target tolerance), the techniques described herein include curing the first adhesive layer CF1. When the first adhesive layer CF1 is cured, the first and second pads PD1 and PD2 and the bump electrodes DC-BP may be fixed to be in contact with each other. As illustrated in FIG. 10, by aligning the first marks MK1 and the second marks MK2, the techniques described herein support accurate mounting and connecting of the data driver DC to the first pad area PA1 of the display panel DP.

FIGS. 11A to 11I are views for explaining a bonding method using an embodiment of the bonding apparatus of FIG. 1.

For example, FIGS. 11A to 11D, 11F, and 11I are cross-sectional views taken along line I′ in FIG. 1.

FIG. 11G illustrates the spectrum parts PLP, the first stage STG1, the display panel DP, the first adhesive layer CF1, the data driver DC, and the pressing parts PSP when viewed in the first direction DR1.

For example, FIGS. 11E and 11H illustrate the display panel DP and the data driver DC when viewed in the plan view.

For convenience of explanation, the first marks MK1 and the second marks MK2 of FIG. 11G are illustrated as a plan view.

For simplicity, only the imaging part CHP of the alignment cameras ACM is illustrated in FIGS. 11A to 11F.

For convenience of description, in FIG. 11G, only the pressing part PSP, the data driver DC, the display panel DP, the first adhesive layer CF1, and the spectrum parts PLP of the bonding apparatus are illustrated.

A bonding apparatus BAP, a display panel DP, a first adhesive layer CF1, and a data driver DC of FIGS. 11A to 11I may be the same as the bonding apparatus BAP, the display panel DP, the first adhesive layer CF1, and the data driver DC of FIGS. 7A, 7B, and 9, and thus, duplicate descriptions thereof will be omitted or simplified.

A method for bonding a data driver DC to the display panel DP in accordance with one or more embodiments of the present disclosure will be described.

Referring to FIGS. 1, 7B, and 11A, the pressing part PSP may include a first pressing part PSP1 and a second pressing part PSP2. The second pressing part PSP2 may be disposed on a bottom surface of the first pressing part PSP1. A length of the second pressing part PSP2 in the first direction DR1 may be less than a length of the first pressing part PSP1 in the first direction.

The display panel DP may be provided on the first stage STG1. The display panel DP may be disposed on the adsorption part SPT and the transmission part TRT. The first area AA1 may overlap the adsorption part SPT. The adsorption holes SH defined in the adsorption part SPT may be converted into a vacuum state by the motor SUM. When the adsorption holes SH are converted into the vacuum state, the display panel DP may be fixed on the adsorption part SPT.

The second area AA2 may be disposed on the transmission part TRT. The second area AA2 may be disposed on the first flat plate portion FR1. The second area AA2 may overlap the first groove GR1. The second area AA2 may be disposed on the spectrum part PLP. Although not shown, the first marks MK1 of FIG. 7B may be disposed on the transmission part TRT. The first marks MK1 of FIG. 7B may be disposed on the spectrum part PLP. The first marks MK1 of FIG. 7B may overlap the spectrum part PLP.

The first adhesive layer CF1 may be disposed on the transmission part TRT. The first adhesive layer CF1 may be disposed on the spectrum part PLP.

The data driver DC may be provided on the second stage STG2. The data driver DC may be disposed in the third groove GR3 defined in a top surface of the second stage STG2. When the data driver DC is disposed on the second stage STG2, the first camera part CMP1 may capture an image of the data driver DC. The first camera part CMP1 may capture an image of the data driver DC to recognize a position of the data driver DC on the second stage STG2.

Referring to FIG. 11B, the second stage STG2 and the data driver DC may move to be adjacent to the first stage STG1. Specifically, the support parts DAR and the flat plate parts HPT connected to the support parts DAR may rotate about a rotation axis parallel to the third direction DR3. As the flat plate parts HPT rotate, the second stage STG2 and the data driver DC disposed on the second stage STG2 may rotate and move about the rotation axis parallel to the third direction.

In an example, based on the movement of the data driver DC and the second stage STG2, the data driver DC may be disposed below the pressing part PSP. The data driver DC may be disposed above the second camera part CMP2.

When the data driver DC is disposed above the second camera part CMP2, the second camera part CMP2 may capture an image of the data driver DC. The second camera part CMP2 may capture an image of the data driver DC to recognize the position of the data driver DC on the second stage STG2.

Referring to FIG. 11C, after the second camera part CMP2 captures the image of the data driver DC, the techniques described herein include moving the pressing part PSP in the third direction DR3 based on the position of the data driver DC recognized by the first and second camera parts CMP1 and CMP2.

In an example, as a result of moving the pressing part PSP in the third direction DR3, the second pressing part PSP2 fixes the data driver DC to the second stage STG2. For example, the second pressing part PSP2 may fix the data driver DC to the second stage STG2 by vacuum suction of the adsorption holes SH.

Referring to FIGS. 9, 11D, and 11E, after the pressing part PSP fixes the data driver DC to the second stage STG2, the pressing part PSP may move away from the driver PST in the third direction DR3. Thereafter, the pressing part PSP may move in the first direction DR1 such that the pressing part PSP is disposed on the first stage STG1. The pressing part PSP may be disposed on the transmission part TRT. The pressing part PSP may be disposed on the spectrum part PLP. The data driver DC may overlap the spectrum PLP. The second marks MK2 may overlap the spectrum part PLP.

When the pressing part PSP is disposed on the spectrum part PLP, the imaging part CHP may capture an image of the first marks MK1 disposed on the display panel DP and the second marks MK2 disposed on the data driver DC. Specifically, although not shown, a lighting device and a prism lens may be disposed inside the spectrum part PLP. When the lighting device emits light toward the prism lens, the prism lens may disperse the light into a spectrum. The light dispersed in the spectrum, may include near-infrared rays irradiated toward the transmission part TRT. In an example, the near-infrared rays may have a wavelength of about 0.72 μm to about 1.3 μm.

The near-infrared rays irradiated toward the transmission part TRT may be reflected by the first marks MK1 and the second marks MK2. The reflected near-infrared rays may be incident to the cameras CM through the prism lens (not shown). The cameras CM may obtain digitized images as illustrated in FIG. 11E by converting light (e.g., including the reflected near-infrared rays) into electrical signals. Thus, the positions of the first marks MK1 and the second marks MK2 may be recognized based on the digitized images. In some aspects, the cameras CM may be near-infrared (NIR) cameras capable of detecting and processing near-infrared rays described herein.

When images of the first and second marks MK1 and MK2 are captured by the imaging parts CHP, the middle controller MP and the upper controller TP may move in at least one of the first direction DR1, the second direction DR, and the third direction DR3 based on the positions of the first and second marks MK1 and MK2.

When the upper controller TP moves, the first stages STG1 connected to the upper controller TP move in at least one direction of the first direction DR1, the second direction DR2, and the third direction DR3 in association with the movement of the upper controller TP. Thus, the positions of the first marks MK1 and the second marks MK2 may be aligned based on the movement of the upper controller TP.

Referring to FIGS. 9 and 11F to 11H, after the first marks MK1 and the second marks MK2 are aligned, the techniques described herein include moving the pressing part PSP in the third direction DR3. When the pressing part PSP moves in the third direction DR3, the data driver DC is provided onto (e.g., pressed onto) the display panel DP. The data driver DC may be disposed on the second area AA2. The display panel DP and the data driver DC may overlap the transmission part TRT. The data driver DC may be disposed on the first pad area PA1. The data driver DC may be disposed on the first adhesive layer CF1.

In an example of providing data driver DC onto the display panel DP (e.g., pressing the data driver DC onto the display panel DP), the data driver DC is electrically connected to the display panel DP, the first bumps BP1 are connected to the first pads PD1, and the second bumps BP2 are connected to the second pads PD2.

When the data driver DC and the display panel DP are electrically connected to each other, the imaging part CHP may capture images of the first marks MK1 and the second marks MK2. The images of the first marks MK1 and the second marks MK2 may be captured at the same time (e.g., the same temporal instance, the same temporal duration, partially overlapping temporal durations, and the like) by the imaging part CHP. The imaging part CHP may recognize the positions of the first marks MK1 and the second marks MK2 based on data included in the captured images.

When the positions of the first marks MK1 and the positions of the second marks MK2 are recognized, the techniques described herein include moving the middle controller MP and the upper controller TP in at least one of the first direction DR1, the second direction DR2, and the third direction DR3 based on the positions of the first and second marks MK1 and MK2. Thus, the first stage STG1 may move. The display panel DP and the data driver DC provided on the first stage STG1 may move in the same direction as the movement direction of the first stage STG1. Thus, the positions of the first marks MK1 and the second marks MK2 may be aligned based on the movement of the first stage STG1.

According to some other techniques different from those described according to the example embodiments of the present disclosure, when the data driver DC is bonded on the display panel DP using an imaging part CHP that does not include the near-infrared (NIR) camera as described herein, the first marks MK1 and the second marks MK2 of the data driver DC and the display panel DP may not be captured at the same time.

Specifically, when the data driver DC is disposed on the display panel DP, light may be blocked by the display panel DP such that the images of the second marks MK2 of the data driver DC are unable to be captured. According to this structure, the positions of the first marks MK1 and the positions of the second marks MK2 may be respectively recognized before the data driver DC is disposed on the display panel DP. The data driver DC and the display panel DP may be aligned and connected to each other based on the recognized positions of the first marks MK1 and the positions of the second marks MK2.

After the images of the second marks MK2 of the data driver DC are captured, when provided to the display panel DP, an error may occur in the process such as shaking of the pressing part PSP or shaking of the first stage STG1. Thus, the bump electrodes DC-BP of the data driver DC may not be in contact with the first pad area PA1 (e.g., due to misalignment), and thus, a defect rate of the display panel DP may increase.

However, performing the bonding process using the bonding apparatus according to the example embodiments of the present disclosure, supports simultaneous recognition of the positions of the first marks MK1 and the positions of the second marks MK2. Specifically, the techniques described herein support recognizing and aligning of the positions of the first marks MK1 and the positions of the second marks MK2 at the same time, before the data driver DC is connected to the display panel DP. After the first and second marks MK1 and MK2 are aligned, the data driver DC may be connected to the display panel DP.

After the data driver DC is connected to the display panel DP, the imaging part CHP may re-recognize the positions of the first marks MK1 and the positions of the second marks MK2 at the same time. The controller MDP may allow the position of the first stage STG1 to move based on the positions of the first marks MK1 and the positions of the second marks MK2. For example, features described herein of the controller MDP support the positioning of the first stage STG1 based on the positions of the first marks MK1 and the positions of the second marks MK2.

Thus, the first marks MK1 and the second marks MK2 may be aligned with each other. The bump electrodes DC-BP of the data driver DC may be aligned with the first pad area PA1. The techniques described herein support increased alignment accuracy, thereby substantially reducing the defective rate of the display panel DP.

After the first marks MK1 and the second marks MK2 are aligned, the first adhesive layer CF1 may be cured. For example, the first adhesive layer CF1 may be thermally cured. In an example, as a result of the curing of the first adhesive layer CF1, the first and second pads PD1 and PD2 and the bump electrodes DC-BP are fixed in contact with each other.

Referring to FIG. 111, when the data driver DC is mounted on the display panel DP, the pressing part PSP may move in the third direction DR3.

FIG. 12 is a cross-sectional view of a bonding apparatus according to another embodiment of the present disclosure.

For example, FIG. 12 is a side view when viewed in the first direction DR1.

Referring to FIG. 12, bonding of one display panel DP and one data driver DC in accordance with one or more embodiments of the present disclosure will be described.

For convenience of explanation, only a pressing part PSP, a first stage STG1, a data driver DC, a display panel DP, a first adhesive layer CF1, and a spectrum parts PLP of a bonding apparatus BAP described herein are illustrated in FIG. 12.

For example, for convenience of explanation, first marks MK1, second marks MK2, a third mark MK3, and a fourth mark MK4 of FIG. 12 are displayed in a plane view.

The pressing part PSP, the first stage STG1, the data driver DC, the display panel DP, and the first adhesive layer CF1 of FIG. 12 may be the same as the pressing part PSP, the first stage STG1, the data driver DC, the display panel DP, and the first adhesive layer CF1 of FIG. 11G, and thus, duplicate descriptions thereof will be omitted or simplified.

In addition, FIG. 12 will be mainly described with differences from FIG. 11G.

Referring to FIG. 12, the display panel DP may include a third mark MK3. The third mark MK3 may be disposed between the first marks MK1. The third mark MK3 may be disposed at a center between the first marks MK1, which are opposite to each other in the second direction DR2.

The data driver DC may include a fourth mark MK4. The fourth mark MK4 may be disposed between the second marks MK2. The fourth mark MK4 may be disposed at the center between second marks MK2 which are opposite to each other in the second direction DR2.

When the data driver DC is connected to the display panel DP, each of the second marks MK2 may be disposed adjacent to the corresponding first mark MK1 of the first marks MK1. The fourth mark MK4 may be disposed to overlap the third mark MK3.

A plurality of spectrum parts PLP may be disposed below the first stage STG1. For example, three spectrum parts PLP are illustrated, but the number of spectrum parts PLP may not be limited thereto.

The three spectrum parts PLP may overlap one display panel DP. That is, although not shown, the alignment camera ACM (see FIG. 3) may include three imaging parts CHP respectively corresponding to the three spectrum parts PLP.

When viewed in the first direction DR1, spectrum parts PLP which overlap an edge of the display panel DP may overlap the first marks MK1 and the second marks MK2. The spectrum parts PLP overlapping the edges of the display panel DP may capture images of the first marks MK1 and the second marks MK2.

When viewed in the first direction DR1, a spectrum part PLP′ disposed in the middle among the spectrum parts PLP may overlap the third mark MK3 and the fourth mark MK4. The techniques described herein may include capturing, using the spectrum part PLP′, images of the third mark MK3 and the fourth mark MK4.

As the third mark MK3 is disposed at the center of the first marks MK1 and the fourth mark MK4 is disposed at a center of the second marks MK2, further utilizing the third mark MK3 and the fourth mark MK4 for aligning the display panel DP and the data driver DC may provide substantially increased accuracy and substantially reduced complexity associated with aligning the display panel DP and the data driver DC. Thus, the defect rate of the display panel DP may be reduced.

FIG. 13 is a perspective view of a bonding apparatus according to at least another embodiment of the present disclosure.

For example, only a portion of the display panel DP′ of FIG. 13 is illustrated.

An alignment cameras ACM, a cover CV, motors SUM, and a controller MDP of FIG. 13 may be the same as the alignment cameras ACM, the cover CV, and the motors SUM, and the controller MDP of FIG. 1, and thus, descriptions thereof will be omitted or simplified.

Referring to FIG. 13, a support SPP′ may be disposed on a second cover CV2. The support SPP′ may be disposed on a top surface of the second cover CV2. The support SPP′ may overlap a first groove GR1 defined in a top surface of the second cover CV2.

A first flat plate portion FR1′ may be disposed on the support SPP′. The first flat plate portion FR1′ may be disposed on the second cover CV2. The first plate portion FR1′ may overlap the first groove GR1. The first flat plate portion FR1′ may overlap spectrum parts PLP.

The first flat plate portion FR1′ may have a rectangular parallelepiped shape. When viewed in the plan view, the first flat plate portion FR1′ may have shorter sides extending in the first direction DR1 and longer sides extending in the second direction DR2.

The first plate portion FR1′ may include quartz. The first plate portion FR1′ may be transparent. The first flat plate portion FR1′ may pass light emitted from the alignment cameras ACM.

The second flat plate portion FR2′ may be disposed on the motors SUM. The second flat plate portion FR2′ may be disposed on the controller MDP. The second flat plate portion FR2′ may be connected to the controller MDP. The second flat plate portion FR2′ may be arranged with the first flat plate portion FR1′ in the first direction DR1. When viewed in the plan view, the second flat plate portion FR2′ may have a rectangular shape.

A first stage STG1′ may be disposed on the first flat plate portion FR1′ and the second flat plate portion FR2′. The first stage STG1′ may overlap the first flat plate portion FR1′ and the second flat plate portion FR2′.

The first stage STG1′ may include a transmission part TRT′ and an adsorption part SPT′. The transmission part TRT′ and the adsorption part SPT′ may be arranged in the first direction DR1. Practically, the transmission part TRT′ and the adsorption part SPT′ may be integrated with each other.

The transmission part TRT′ may be disposed on the first flat plate portion FR1. The transmission part TRT′ may be disposed on the second cover CV2. The transmission part TRT′ may overlap the first groove GR1 defined in a top surface of the second cover CV2. The transmission part TRT′ may overlap the spectrum parts PLP.

The adsorption part SPT′ may be disposed on the second flat plate portion FR2′. The adsorption part SPT′ may overlap the second flat plate portion FR2′. The adsorption part SPT′ may be connected to the motors SUM and the controller MDP.

A plurality of adsorption holes SH may be defined in a top surface of the adsorption part SPT′. The adsorption holes SH may be converted into a vacuum state by the motors SUM disposed below the adsorption part SPT′. When the adsorption holes SH are converted into a vacuum state, the display panel DP′ may be fixed to the first stage STG1′.

A display panel DP′ may be disposed on the top surface of the first stage STG1′. The display panel DP′ may be fixed to the first stage STG1′ by the adsorption holes SH. An area adjacent to one side of opposite sides of the display panel DP′ in the first direction DR1 may overlap the first flat plate portion FR1. The area adjacent to the one side of the display panel DP′ may overlap the spectrum parts PLP. The one side of the display panel DP′ may be defined as a side overlapping the cover CV.

When viewed in the plan view, the display panel DP′ may have a rectangular shape. Although not shown, when viewed in the plan view, the display panel DP′ may have shorter sides extending in the first direction DR1 and longer sides extending in the second direction DR2.

The spectrum parts PLP of the plurality of alignment cameras ACM may be disposed in the second groove GR2 defined in the second cover CV2. The spectrum parts PLP may overlap the first groove GR1. The spectrum parts PLP may overlap the first flat plate portion FR1. The spectrum parts PLP may overlap the transmission part TRT′. The spectrum parts PLP may overlap the one side of the display panel DP′.

That is, the spectrum parts PLP may overlap one of the sides of the display panel DP′. In the example of FIG. 13, eight spectrum parts PLP are illustrated, but the number of the spectrum parts PLP overlapping the one side of the display panel DP′ is not limited thereto.

FIG. 14 is a perspective view of a bonding apparatus according to at least another embodiment of the present disclosure.

Alignment cameras ACM, a cover CV, motors SUM, and controller MDP of FIG. 14 may be the same as the alignment cameras ACM, cover unit CV, motor units SUM, and control unit MDP of FIG. 1, and a support SPP′, a first flat plate portion FR1, a second flat plate portion FR2′, and a first stage STG1′ of FIG. 14 are the same as the support SPP′, the first flat plate part FR1′, the second flat plate part FR2′, and the first stage STG1′ of FIG. 13, and thus, duplicate descriptions thereof will be omitted or simplified.

For convenience of explanation, a first flat plate portion FR1, a second flat plate portion FR2′, and a support SPP′, and alignment cameras ACM, which are adjacent to one side of the opposite sides of the display panel DP′ in the first direction DR1 will be described, and the first flat plate portion FR1′, the second flat plate portion FR2′, the support SPP′, and the alignment cameras ACM adjacent to the other side of the display panel DP′ may be substantially the same except that the above-described components are symmetrical to each other in the first direction DR1, and thus, duplicate descriptions thereof will be omitted.

Referring to FIG. 14, the display panel DP′ may be disposed on the first stage STG1′. The display panel DP′ may be fixed to the first stage STG1′ by the adsorption holes SH′. Both sides of the display panel DP′ that are opposite to each other in the first direction DR1 may overlap the first flat plate portions FR1. Both sides of the display panel DP′, which are opposite to each other in the first direction DR1 may overlap the first grooves GR1.

Two pairs of alignment cameras ACM may be disposed to be symmetrical to each other in the first direction DR1. The alignment cameras ACM adjacent to one side of the display panel DP′, which are opposite to each other in the first direction DR1, may be disposed adjacent to the cover CV. The pair of alignment cameras ACM may be spaced apart from each other in the second direction DR2. The spectrum parts PLP may be disposed in the second groove GR2.

Each of the pair of spectrum parts PLP may overlap a corresponding edge of edges of the display panel DP′, which are opposite to each other in the second direction DR2. For example, in FIG. 14, one edge of the display panel DP′ may overlap two spectrum parts PLP. However, example embodiments of the present disclosure are not limited thereto, and one edge of the display panel DP′ may overlap three or more spectrum parts PLP or one spectrum part PLP.

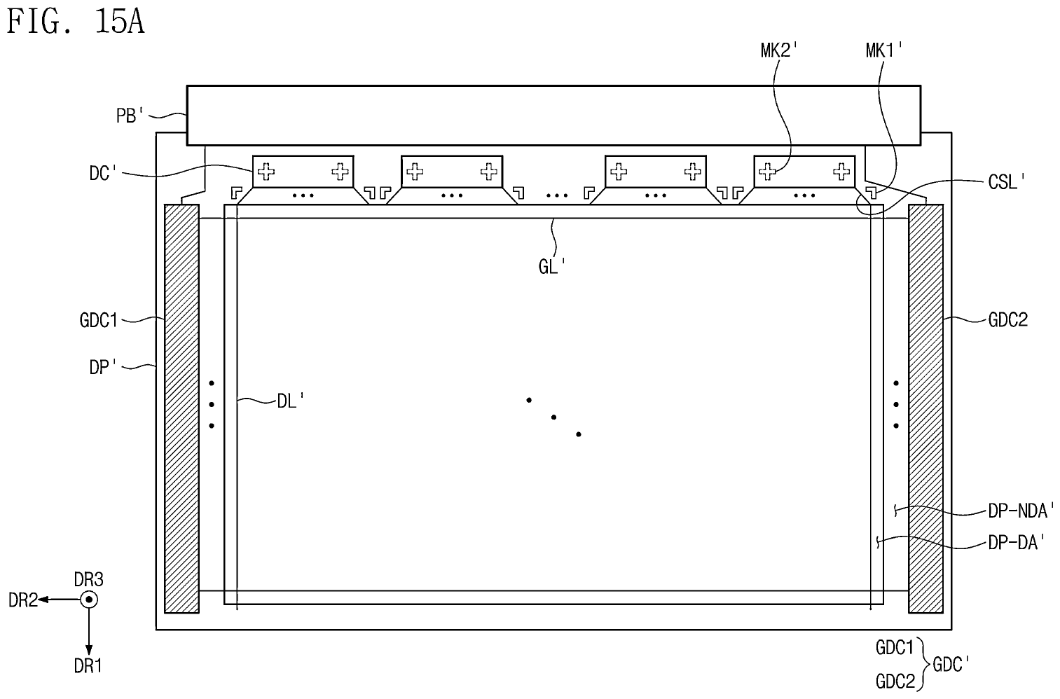

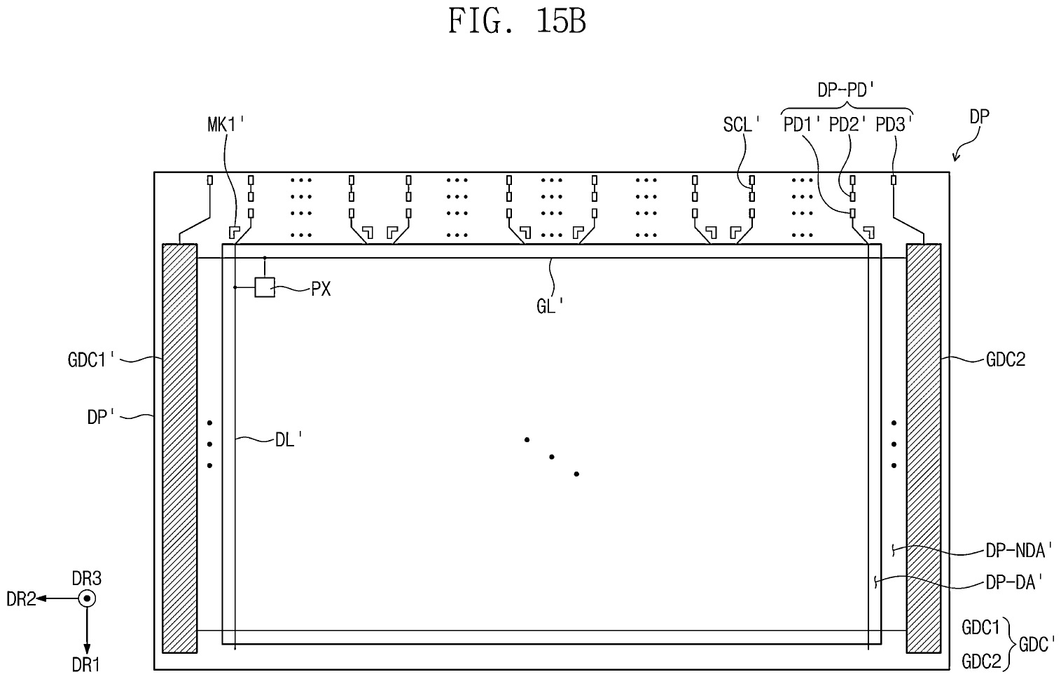

FIGS. 15A and 15B are example views of embodiments of a display panel of FIGS. 13 and 14.

For example, FIGS. 15A and 15B are illustrated in a plan view.

For example, FIG. 15B is a cross-sectional view of a display panel DP′ in which a data driver DC′ and a circuit board PB′ of FIG. 7A are separated from each other.

For example, a data driver DC′ and a circuit board PB′ of FIGS. 15A and 15B may be substantially the same as the data driver DC and the circuit board PB of FIGS. 7A and 7B except for the number and size thereof.

Referring to FIG. 15A, the display panel DP′ may extend longer in the second direction DR2 than in the first direction DR1. The display panel DP′ may have a plane defined by the first and second directions DR1 and DR2.

The display panel DP′ may include a display area DP-DA′ displaying an image and a non-display area DP-NDA′ adjacent to the display area DP-DA′. The display area DP-DA′ may be an area on which an image is substantially displayed, and the non-display area DP-NDA′ may be an area on which an image is not displayed.

The display panel DP′ may include a plurality of gate lines GL′, a plurality of data lines DL′, and a plurality of pixels (not shown). The gate lines GL′ may extend in the second direction DR2 and may be arranged in the first direction DR1. The data lines DL′ may extend in the first direction DR1 and may be arranged in the second direction DR2.

Although not shown, each of the pixels (not shown) may be electrically connected to a corresponding gate line GL′ of the gate lines GL′ and corresponding data lines DL′ of the data lines DL′.

The gate driver GDC′ may sequentially output gate signals to the gate lines GL′. Pixels (not shown) may be sequentially scanned by the gate signal.

The gate driver GDC′ may include a first gate driver GDC1 and a second gate driver GDC2. The first and second gate drivers GDC1 and GDC2 may be disposed adjacent to opposite sides of the display panel DP′ in the second direction DR2. The first and second gate drivers GDC1 and GDC2 may be disposed in the non-display area DP-NDA.

The first gate driver GDC1 may be electrically connected to respective first ends of the gate lines GL′, and the second gate driver GDC2 may be electrically connected to respective second ends of the gate lines GL′. Each of the first and second gate drivers GDC1 and GDC2 may include a shift register that sequentially outputs a gate signal. The first and second gate drivers GDC1 and GDC2 may simultaneously operate to simultaneously output gate signals to the gate lines GL′. Thus, each of the gate lines GL′ may receive gate signals from the first and second gate drivers GDC1 and GDC2 through the first and second ends of the gate line GL′.

In FIG. 15A, a structure in which two gate drivers GDC1 and GDC2 are electrically connected to both ends of gate lines GL′ is illustrated, but example embodiments of the present disclosure are not limited thereto.

Referring to FIGS. 13, 15A, and 15B, the display panel DP′ may include a plurality of signal pads DP-PD′. The signal pads DP-PD′ may include first pads PD1′, second pads PD2′, and third pads PD3′.

Each of the first pads PD1′ may be connected to a corresponding data line DL′ of the data lines DL′. Although not shown, the first pads PD1′ and the second pads PD2′ may be electrically connected to each other. The second pads PD2′ may be connected to the third pads PD3′ through connection signal lines S-CL′.

The display panel DP′ may include a plurality of first marks MK1′. The first marks MK1′ may be disposed adjacent to data drivers DC′, which will be described later herein. In an example, the plurality of first marks MK1′ may be arranged in the second direction DR2.

The plurality of data drivers DC′ may be mounted adjacent to one of the opposite sides of the display panel DP′ in the first direction DR1. The first pads PD1′ and the second pads PD2′ may be connected to the data driver DC′. Although not shown, a plurality of bumps may be disposed on a bottom surface of the data driver DC′. The plurality of bumps may be connected to the first and second pads PD1′ and PD2′.

The data drivers DC′ may be arranged in the second direction DR2. The data driver DC′ may generate a driving signal associated with the operation of the display panel DP′ based on a control signal transmitted from the circuit board PB′, which will be described later.

Each of the data drivers DC′ may include second marks MK2′. For example, the second marks MK2′ are illustrated as dotted lines. The second marks MK2′ may be disposed at sides of the data drivers DC′ opposite to each other in the second direction DR2.

When viewed in the plan view, an intermediate point between the first marks MK1′ and an intermediate point between the second marks MK2′ may be aligned to match each other. Specifically, when the display panel DP′ is disposed on the first stage STG1′ illustrated in FIG. 13, the data driver DC′ may be provided on the display panel DP′. When the display panel DP′ and the data driver DC′ are connected, the alignment cameras ACM may simultaneously capture images of the first marks MK′ and the second marks MK2′.

The controller MDP may move in at least one direction of the first direction DR1, the second direction DR2, and the third direction DR3 based on the positions of the first marks MK′ and the positions of the second marks MK2′ captured by the alignment cameras ACM. The first marks MK′ and the second marks MK2′ may be aligned. Thus, the bonding apparatus BAP′ may correct errors even when the errors occur in the process. Therefore, the data driver DC′ may be aligned and mounted on the display panel DP′ to reduce a defective rate of the display panel DP′.

The circuit board PB′ may be mounted adjacent to one of opposite sides of the display panel DP′ in the first direction DR1. The circuit board PB′ may be disposed adjacent to one of opposite sides of the data drivers DC′ in the first direction DR1. One sides of the data drivers DC′ may be defined as opposite sides to other sides adjacent to the display area DP-DA. Expressed another way, other sides of the data drivers DC′ in the first direction DR1 may be defined as opposite to the sides adjacent to the display area DP-DA.

Although not shown, the circuit board PB′ may be bent and disposed on a rear surface of the display panel DP′.

The circuit board PB′ may be in contact with and be connected to the third pads PD3′. Although not shown, a plurality of circuit pads may be disposed on a bottom surface of the circuit board PB′. The circuit pads may contact the third pads PD3′. Thus, the circuit board PB′ may be electrically connected to the display panel DP′.

According to the embodiment of the present disclosure, when the display panel including the first mark and the data driver including the second mark are connected to each other, the alignment camera disposed below the display panel may capture the first mark and the second mark at the same time. Therefore, even after the display panel and the data driver are connected to each other, further errors that may occur in the bonding process may be corrected to more accurately bond the display panel to the data driver.

It will be apparent to those skilled in the art that various modifications and variations can be made in the present disclosure. Thus, it is intended that the present disclosure covers the modifications and variations of this invention provided they come within the scope of the appended claims and their equivalents. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A bonding apparatus comprising:
a first stage on which a display panel comprising a first mark is disposed;
a pressing part disposed above the first stage and configured to provide a data driver comprising a second mark on the display panel; and
an alignment camera disposed below the first stage,
wherein, when the data driver is provided on the display panel such that the data driver and the display panel are connected to each other, the alignment camera is configured to capture images of the first mark and the second mark at a same temporal instance.

2. The bonding apparatus of claim 1, further comprising a controller disposed below the first stage,
wherein a plane of the first stage is defined by a first direction and a second direction crossing the first direction, and
when the data driver and the display panel are connected to each other, the controller is configured to move the first stage in at least one direction of the first direction, the second direction, or a third direction crossing the plane.

3. The bonding apparatus of claim 2, wherein the controller is configured to move the first stage based on a position of the first mark, which is imaged by the alignment camera, and a position of the second mark, which is imaged by the alignment camera.

4. The bonding apparatus of claim 2, wherein the alignment camera comprises:
a spectrum part disposed below the first stage;
a barrel part connected to the spectrum part and extending in the first direction;
a camera connected to a first portion of the barrel part; and
an adjusting part coupled to the barrel part,
wherein:
the adjusting part is configured to move the spectrum part and the camera in at least one direction of the first direction, the second direction, and the third direction; and
the spectrum part is coupled to a second portion of the barrel part, wherein the second portion is opposite to the first portion in the first direction.

5. The bonding apparatus of claim 1, wherein the first stage comprises:
an adsorption part in which a plurality of adsorption holes are defined; and
a transmission part arranged with the adsorption part in a first direction and disposed on the alignment camera.

6. The bonding apparatus of claim 5, wherein, when the data driver and the display panel are connected, the first mark and the second mark overlap the transmission part.

7. The bonding apparatus of claim 5, wherein the alignment camera is configured to transmit near-infrared rays toward the transmission part and capture images of the first mark and the second mark based on the transmitted near-infrared rays.

8. The bonding apparatus of claim 5, further comprising:
a first flat plate portion disposed below the transmission part; and
a second flat plate portion arranged with the first flat plate portion in the first direction and disposed below the adsorption part,
wherein the first flat plate portion comprises quartz.

9. The bonding apparatus of claim 1, further comprising:
a second stage on which the data driver is disposed, wherein a plane of the second stage is defined by a first direction and a second direction crossing the first direction; and
a driver connected below the second stage and configured to rotate around a rotation axis parallel to a third direction crossing the plane,
wherein the driver rotates such that the second stage is disposed below the pressing part.

10. The bonding apparatus of claim 9, further comprising a first camera part disposed on the second stage and the driver,
wherein the first camera part is configured to capture an image of the data driver disposed on the second stage, and
wherein rotation of the driver is based on the captured image.

11. The bonding apparatus of claim 9, wherein, when the second stage is disposed below the pressing part, the pressing part is configured to transfer the data driver to the first stage, wherein transferring the data driver to the first stage comprises adsorbing the data driver to the first stage.

12. The bonding apparatus of claim 9, further comprising a second camera part disposed below the pressing part and the second stage,
wherein the second camera part is configured to capture an image of the data driver disposed on the second stage when the second stage is disposed below the pressing part.

13. The bonding apparatus of claim 1,
wherein the align camera is provided in plurality, and
wherein each of the plurality of alignment cameras overlaps a corresponding edge of edges of the display panel.

14. The bonding apparatus of claim 1,
wherein the align camera is provided in plurality, and
wherein each of the plurality of alignment cameras overlaps a corresponding side of sides of the display panel.

15. A bonding method comprising:
providing a display panel comprising a first mark on a first stage, wherein a plane of the first stage is defined by a first direction and a second direction crossing the first direction;
connecting a data driver comprising a second mark to the display panel;
capturing a first image of the first mark and a second image of the second mark by an alignment camera disposed below the first stage, wherein the first image of the first mark and the second image of the second mark are captured at a same temporal instance; and
aligning the display panel and the data driver.

16. The bonding method of claim 15, wherein the connecting of the data driver comprises transferring the data driver onto the display panel by using an adsorption part.

17. The bonding method of claim 15, wherein the aligning of the display panel and the data driver comprises moving the first stage in at least one direction of the first direction, the second direction, or a third direction crossing the plane by a controller disposed below the first stage.

18. The bonding method of claim 15, wherein the first stage comprises:
an adsorption part in which a plurality of adsorption holes are defined; and
a transmission part arranged with the adsorption part in the first direction,
wherein, when the display panel and the data driver are connected, the first mark and the second mark overlap the transmission part.

19. The bonding method of claim 15, wherein the alignment camera comprises:
a spectrum part disposed below the first stage;
a barrel part connected to the spectrum part and extending in the first direction;
a camera connected to a first portion of the barrel part; and
an adjusting part coupled to the barrel part,
wherein:
capturing the first image and the second image, aligning the display panel and the data driver, or both comprises moving, by the adjusting part, the spectrum part and the camera in at least one direction of the first direction, the second direction, and a third direction crossing the plane; and
the spectrum part is coupled to a second portion of the barrel part, wherein the second portion is opposite to the first portion in the first direction.

20. The bonding method of claim 15, wherein capturing the first image and the second image comprises transmitting near-infrared rays to the first mark and the second mark by the alignment camera.
